(19) United States
(12) Patent Application Publication
(10) Pub. No.: US 2026/0223435 A1
(43) Pub. Date: Jul. 30, 2026

(54) SEMICONDUCTOR DEVICE

(71) Applicant: FUJI ELECTRIC CO., LTD., Kanagawa (JP)

(72) Inventor: Motoyoshi KUBOUCHI, Matsumoto-city (JP)

(21) Appl. No.: 19/575,819

(22) Filed: Mar. 23, 2026

Related U.S. Application Data
(63) Continuation of application No. PCT/JP2025/005248, filed on Feb. 17, 2025.

(30) Foreign Application Priority Data
Apr. 15, 2024 (JP) 2024-065602

(51) Int. Cl. H10D 84/00; H10D 8/00; H10D 12/00; H10D 62/10; H10D 62/53; H10D 62/60

(52) U.S. Cl. CPC H10D 84/161; H10D 8/422; H10D 12/481; H10D 62/105; H10D 62/126; H10D 62/53; H10D 62/60

(57) ABSTRACT

Provided is a semiconductor device including a transistor section and a diode section, the transistor section has a first transistor region and a second transistor region which is provided between the first transistor region and the diode section, a first mesa portion of the first transistor region has a first region of the first conductivity type, and a second mesa portion of the second transistor region has a second region of the first conductivity type with a doping concentration higher than that of the first region.

The contents of the following patent application(s) are incorporated herein by reference:

NO. 2024-065602 filed in JP on April 15, 2024

NO. PCT/JP2025/005248 filed in WO on February 17, 2025.

### BACKGROUND

### 1. TECHNICAL FIELD

The present invention relates to a semiconductor device.

### 2. RELATED ART

Patent Document 1 describes "An optional n-doped carrier confinement region may be arranged between the p-doped body region 130 and the n-doped drift region 115, e.g. in a mesa region between neighboring second trench structures 128 (not illustrated in FIG. 4)., and "The drift region 115 arranged between the emitter efficiency adjustment region 114 and the second main surface 111 of the semiconductor substrate 102 may have a minority carrier lifetime that is larger than 100 μs. Patent Document 2 describes "The semiconductor device 200 has the accumulation region 16 in both the transistor section 70 and the diode section 80. The dopant (donor in the present example) in the accumulation region 16 is accumulated at a higher concentration than that in the drift region 18.

### RELATED ART DOCUMENTS

### Patent Documents

Patent Document 1: US2022/0384624

Patent Document 2: Japanese Patent Application Publication No. 2018-174295

### BRIEF DESCRIPTION OF THE DRAWINGS

FIG. 1 is a top view illustrating an example of a semiconductor device 100 according to an embodiment of the present invention.

FIG. 2 illustrates an enlarged view of a region D in FIG. 1.

FIG. 3 illustrates an example of a cross section e-e in FIG. 2.

FIG. 4 is a view illustrating an example of a cross section f-f in FIG. 2.

FIG. 5 illustrates an example of a doping concentration distribution along a line r-r' and a line s-s' in FIG. 3.

FIG. 6 is an enlarged view in a vicinity of a trench contact portion 58 in a boundary region 200.

FIG. 7 illustrates an arrangement example of a first transistor region 201 and a second transistor region 202 in a top view.

FIG. 8 illustrates another configuration example of a first mesa portion 61, a second mesa portion 62, and a third mesa portion 63.

FIG. 9 illustrates an example of a doping concentration distribution along the line r-r' and the line s-s' in FIG. 8.

FIG. 10 illustrates another configuration example of the first mesa portion 61, the second mesa portion 62, and the third mesa portion 63.

FIG. 11 illustrates an example of a doping concentration distribution along the line r-r' and the line s-s' in FIG. 10.

FIG. 12 illustrates another configuration example of the first mesa portion 61, the second mesa portion 62, and the third mesa portion 63.

FIG. 13 illustrates an example of a doping concentration distribution along the line r-r' and the line s-s' in FIG. 12.

FIG. 14 illustrates another configuration example of the first mesa portion 61, the second mesa portion 62, and the third mesa portion 63.

FIG. 15 illustrates an example of a doping concentration distribution along the line r-r' and the line s-s' in FIG. 14.

FIG. 16 illustrates another example of the cross section e-e in FIG. 2.

FIG. 17 illustrates another example of the cross section e-e in FIG. 2.

FIG. 18 illustrates another example of the enlarged view of the region D in FIG. 1.

FIG. 19 illustrates another example of the enlarged view of the region D in FIG. 1.

FIG. 20 illustrates an example of a cross section e-e in FIG. 19.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solution of the invention.

As used herein, one side in a direction parallel to a depth direction of a semiconductor substrate is referred to as "upper" and the other side is referred to as "lower". One surface of two principal surfaces of a substrate, a layer or other member is referred to as an upper surface, and the other surface is referred to as a lower surface. "Upper" and "lower" directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components and do not limit a specific direction. For example, the Z axis is not limited to indicate a height direction with respect to a ground. It should be noted that a +Z axis direction and a -Z axis direction are directions opposite to each other. If the Z axis direction is described without describing the signs, it means that the direction is parallel to the +Z axis and the -Z axis.

In the present specification, orthogonal axes parallel to an upper surface and a lower surface of a semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis direction and the Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region doped with an impurity is described as a P type or an N type. In the present specification, the impurities may particularly mean either a donor of the N type or an acceptor of the P type and may be described as dopants. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration in any position is given as N_{D} - N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by a combination of at least a vacancy (V) and hydrogen (H). Alternatively, interstitial Si-H which is a combination of interstitial silicon (Si-i) and hydrogen in a silicon semiconductor also functions as the donor which supplies electrons. In the present specification, the VOH defect or interstitial Si-H may be referred to as a hydrogen donor.

In the semiconductor substrate in the present specification, a bulk donor of the N type is distributed throughout. The bulk donor is a dopant donor substantially uniformly contained in an ingot during the manufacture of the ingot from which the semiconductor substrate is made. The bulk donor in the present example is an element other than hydrogen. The bulk donor dopant is, for example, phosphorous, antimony, arsenic, selenium, or sulfur but is not limited to these. The bulk donor in the present example is phosphorous. The bulk donor is also contained in a region of the P type. The semiconductor substrate may be a wafer cut out from a semiconductor ingot or may be a chip obtained by singulating the wafer. The semiconductor ingot may be manufactured by either a Czochralski method (CZ method), a magnetic field applied Czochralski method (MCZ method), or a float zone method (FZ method). The ingot in the present example is manufactured by the MCZ method. An oxygen concentration contained in a substrate manufactured by the MCZ method is 1 × 10¹⁷ to 7 × 10¹⁷/cm³. An oxygen concentration contained in a substrate manufactured by the FZ method is 1 × 10¹⁵to 5 × 10¹⁶/cm³. As the oxygen concentration is higher, hydrogen donors tend to be more easily generated. The bulk donor concentration may use a chemical concentration of the bulk donor distributed throughout the semiconductor substrate or may be set as a value from 90% to 100% of the chemical concentration. In addition, as the semiconductor substrate, a non-doped substrate not containing a dopant such as phosphorous may be used. In that case, the bulk donor concentration (D0) of the non-doped substrate is, for example, greater than or equal to 1 × 10¹⁰/cm³ and less than or equal to 5 × 10¹²/cm³. The bulk donor concentration (D0) of the non-doped substrate is preferably greater than or equal to 1 × 10¹¹/cm³. The bulk donor concentration (D0) of the non-doped substrate is preferably less than or equal to 5 × 10¹²/cm³. Each concentration in the present invention may be set as a value at room temperature. As an example, a value at 300K (Kelvin) (about 26.9 degrees C) may be used as the value at room temperature.

In the present specification, a description of a P+ type or an N+ type means a higher doping concentration than that of the P type or the N type, and a description of a P- type or an N- type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before some calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be set as a value in a thermal equilibrium state. In addition, in a region of the N type, the donor concentration is sufficiently greater than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor, or net doping is substantially uniform in a region, or the like, an average value of the concentration of the donor, acceptor, or net doping in the region may be set as the concentration of the donor, acceptor, or net doping. In the present specification, atоms/cm³ or /cm³ is used to indicate a concentration per unit volume. This unit is used for a donor or acceptor concentration in a semiconductor substrate, or a chemical concentration. A notation of atоms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder of a crystal structure (disorder) due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

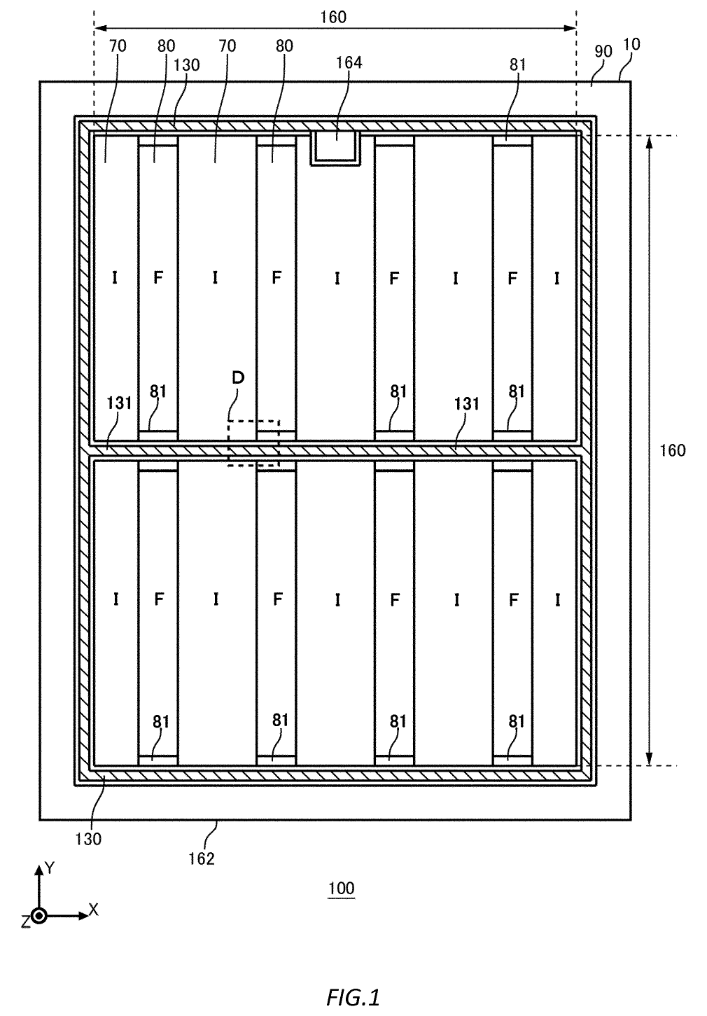

FIG. 1 is a top view illustrating an example of a semiconductor device 100 according to an embodiment of the present invention. FIG. 1 illustrates a position of each member projected onto an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When the top view is simply mentioned in the present specification, it means that the semiconductor substrate 10 is viewed from an upper surface side. The semiconductor substrate 10 in the present example has two sets of end sides 162 opposite to each other in the top view. In FIG. 1, the X axis and the Y axis are parallel to any of the end sides 162. In addition, the Z axis is perpendicular to the upper surface of the semiconductor substrate 10.

The semiconductor substrate 10 is provided with an active section 160. The active section 160 is a region where a main current flows in a depth direction between the upper surface and a lower surface of the semiconductor substrate 10 when the semiconductor device 100 operates. An emitter electrode is provided above the active section 160 but is omitted in FIG. 1. The active section 160 may refer to a region which overlaps the emitter electrode in the top view. In addition, a region sandwiched between active sections 160 in the top view may also be included in the active section 160.

The active section 160 is provided with a transistor section 70 including a transistor element such as an insulated gate bipolar transistor (IGBT) and a diode section 80 including a diode element such as a freewheeling diode (FWD). In the example of FIG. 1, the transistor sections 70 and the diode sections 80 are alternately arranged along a predetermined first direction (X axis direction in the present example) on the upper surface of the semiconductor substrate 10. The semiconductor device 100 in the present example is a reverse conduction type IGBT (RC-IGBT). A boundary region may be arranged between the transistor section 70 and the diode section 80 in the X axis direction but is omitted in FIG. 1.

In FIG. 1, a region where each of the transistor sections 70 is arranged is indicated by a symbol "I", and a region where each of the diode sections 80 is arranged is indicated by a symbol "F". In the present specification, a direction different from the first direction in the top view may be referred to as a second direction (Y axis direction in FIG. 1). The second direction may be a direction perpendicular to the first direction. Each of the transistor section 70 and the diode section 80 may have a longitudinal length in the second direction. In other words, a length of the transistor section 70 in the Y axis direction is larger than a width in the X axis direction. Similarly, a length of the diode section 80 in the Y axis direction is larger than a width in the X axis direction. The second direction of the transistor section 70 and the diode section 80 may be the same as a longitudinal direction of each trench portion and a longitudinal direction of the mesa portions described below.

Each of the diode sections 80 includes a cathode region of an N+ type in a region in contact with the lower surface of the semiconductor substrate 10. In the present specification, a region where the cathode region is provided is referred to as the diode section 80. In other words, the diode section 80 is a region which overlaps the cathode region in the top view. On the lower surface of the semiconductor substrate 10, a collector region of the P+ type may be provided in a region other than the cathode region. In the present specification, the diode section 80 may also include an extension region 81 where the diode section 80 extends to a gate runner described below in the Y axis direction. The collector region is provided on a lower surface of the extension region 81.

The semiconductor device 100 may have one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. When the semiconductor device 100 is mounted, each pad may be connected to an external circuit via a runner such as a wire.

A gate potential is applied to the gate pad 164. The gate pad 164 is electrically connected to a conductive portion of a gate trench portion of the active section 160. The semiconductor device 100 includes a gate runner that connects the gate pad 164 and the gate trench portion. In FIG. 1, the gate runner is hatched with diagonal lines.

The gate runner in the present example has an outer circumferential gate runner 130 and an active-side gate runner 131. The outer circumferential gate runner 130 is arranged between the active section 160 and the end side 162 of the semiconductor substrate 10 in the top view. The outer circumferential gate runner 130 in the present example surrounds the active section 160 in the top view. A region surrounded by the outer circumferential gate runner 130 in the top view may be set as the active section 160. In addition, a well region is formed below the gate runner. The well region is a P type region having a higher concentration than the base region described below, and is formed up to a position deeper than a position of the base region from the upper surface of the semiconductor substrate 10. A region enclosed by the well region in a top view may be the active section 160.

An outer circumferential gate runner 130 is connected to the gate pad 164. The outer circumferential gate runner 130 is arranged above the semiconductor substrate 10. The outer circumferential gate runner 130 may be a metal wiring including such as aluminum, or a wiring formed of a semiconductor such as polysilicon doped with an impurity.

The active-side gate runner 131 is provided in the active section 160. Providing the active-side gate runner 131 in the active section 160 can reduce a variation in a runner length from the gate pad 164 for each region of the semiconductor substrate 10.

The outer circumferential gate runners 130 and the active-side gate runner 131 are connected to the gate trench portion of the active section 160. The outer circumferential gate runners 130 and the active-side gate runner 131 are arranged above the semiconductor substrate 10. The outer circumferential gate runner 130 and the active-side gate runner 131 may be a metal wiring including such as aluminum, or a wiring formed of a semiconductor such as polysilicon doped with an impurity.

The active-side gate runner 131 may be connected to the outer circumferential gate runner 130. The active-side gate runner 131 in the present example is provided extending in the X axis direction so as to cross the active section 160 from one outer circumferential gate runner 130 to another outer circumferential gate runner 130 which sandwich the active section 160 so that the active section 160 is divided into approximately equal parts in the Y axis direction. When the active section 160 is divided by the active-side gate runner 131, the transistor sections 70 and the diode sections 80 may be alternately arranged in the X axis direction in each divided region.

The semiconductor device 100 may include a temperature sensing portion (not illustrated) that is a P-N junction diode formed of polysilicon or the like, and a current detection portion (not illustrated) that simulates an operation of the transistor section provided in the active section 160. Note that the temperature sensing portion may be connected to an anode pad and a cathode pad arranged in a vicinity of the end side 162.

The semiconductor device 100 in the present example includes an edge termination structure portion 90 between the active section 160 and the end side 162 in the top view. The edge termination structure portion 90 in the present example is arranged between the outer circumferential gate runner 130 and the end side 162. The edge termination structure portion 90 relaxes an electric field strength on the upper surface side of the semiconductor substrate 10. The edge termination structure portion 90 may include at least one of a guard ring, a field plate, or a RESURF which are annularly provided surrounding the active section 160.

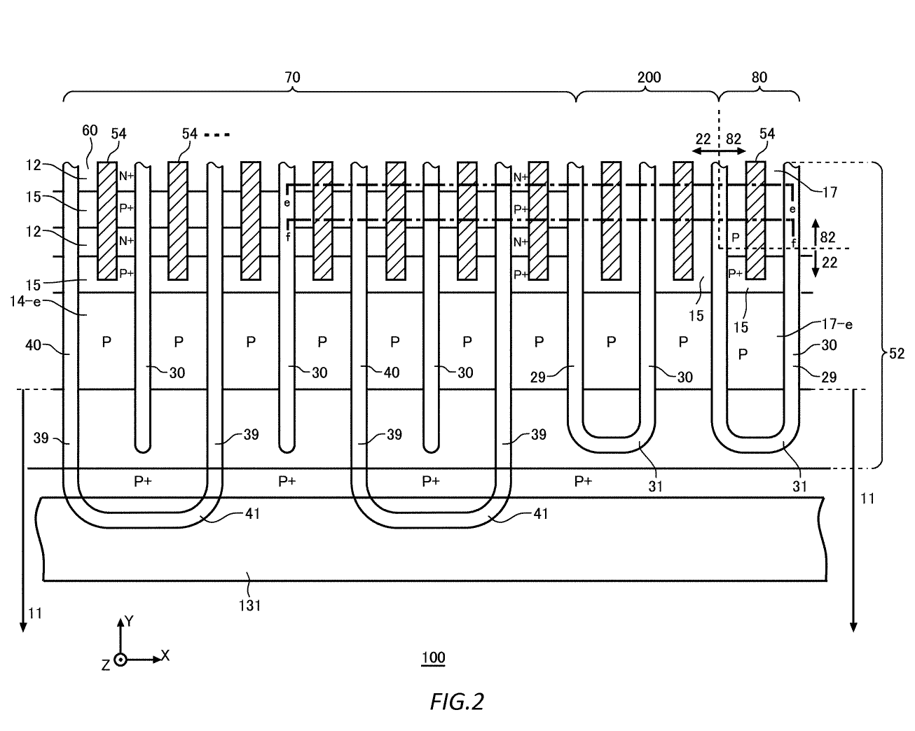

FIG. 2 illustrates an enlarged view of a region D in FIG. 1. The region D is a region including a transistor section 70, a diode section 80, and an active-side gate runner 131. Although omitted in FIG. 1, a boundary region 200 is arranged between the transistor section 70 and the diode section 80 in the X axis direction. In the present example, the boundary region 200 may be a part of the transistor section 70, that is, the transistor section 70 may have the boundary region 200. Instead of this, the boundary region 200 may be a part of the diode section 80. Note that in the following description, the transistor section 70, the diode section 80, and the boundary region 200 may be separately described as mutually different parts.

The semiconductor device 100 in the present example includes a gate trench portion 40, a dummy trench portion 30, a well region 11, an emitter region 12, a base region 14, and a contact region 15 that are provided inside the upper surface side of the semiconductor substrate 10. The gate trench portion 40 and the dummy trench portion 30 each are an example of the trench portion. In addition, the semiconductor device 100 in the present example includes an emitter electrode 52 and the active-side gate runner 131 that are provided on or above the upper surface of the semiconductor substrate 10. The emitter electrode 52 is an example of a metal electrode. The emitter electrode 52 and the active-side gate runner 131 are provided in isolation from each other.

An interlayer insulating film is provided between the emitter electrode 52 and the active-side gate runner 131, and the upper surface of the semiconductor substrate 10, but the interlayer insulating film is omitted in FIG. 2. In the interlayer insulating film in the present example, a contact hole 54 is provided penetrating the interlayer insulating film. In FIG. 2, each contact hole 54 is hatched with the diagonal lines.

The emitter electrode 52 is provided above the gate trench portions 40, the dummy trench portions 30, the well region 11, the emitter regions 12, the base regions 14, and the contact regions 15. The emitter electrode 52 is in contact with the emitter regions 12, the contact regions 15, and the base regions 14 at the upper surface of the semiconductor substrate 10, through the contact holes 54. In addition, the emitter electrode 52 is connected to a dummy conductive portion in the dummy trench portion 30 through the contact hole provided in the interlayer insulating film. The emitter electrode 52 may be connected to the dummy conductive portion of the dummy trench portion 30 at an edge of the dummy trench portion 30 in the Y axis direction. The dummy conductive portions of the dummy trench portions 30 may not be connected to the emitter electrode 52 and a gate conductive portion, and may be controlled to be at a potential different from a potential of the emitter electrode 52 and a potential of the gate conductive portion.

The active-side gate runner 131 is connected to the gate trench portion 40 through the contact hole provided in the interlayer insulating film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material containing metal. FIG. 2 illustrates a range where the emitter electrode 52 is provided. For example, at least some region of the emitter electrode 52 is formed of aluminum or an alloy main component of which is aluminum, for example, a metal alloy such as AlSi or AlSiCu. The emitter electrode 52 may have a barrier metal formed of titanium, a titanium compound, or the like in a layer below a region formed of aluminum or the like. Further, a plug portion, which is formed by embedding tungsten or the like so as to be in contact with the barrier metal and aluminum or the like, may be included in the contact hole.

The base region 14 is a region of a second conductivity type. The well region 11 is provided overlapping the active-side gate runner 131. The well region 11 is provided so as to extend with a predetermined width even in a range not overlapping the active-side gate runner 131. The well region 11 in the present example is provided away from an end of the contact hole 54 in the Y axis direction toward the active-side gate runner 131 side. The well region 11 is a region of the second conductivity type having a higher doping concentration than the base region 14. The base region 14 in the present example is of the P type, and the well region 11 is of the P+ type.

Each of the transistor section 70, the diode section 80, and the boundary region 200 includes a plurality of trench portions arranged in the first direction. The plurality of trench portions extend in the second direction perpendicular to the first direction on a front surface side of the semiconductor substrate 10. The second direction is an example of a predetermined trench extension direction. The plurality of trench portions have the gate trench portions 40.

In the transistor section 70 in the present example, one or more gate trench portions 40 and one or more dummy trench portions 30 are alternately provided along the first direction. In the diode section 80 in the present example, the plurality of dummy trench portions 30 are provided along the first direction. In the diode section 80 in the present example, the gate trench portion 40 is not provided. In the boundary region 200 in the present example, the plurality of dummy trench portions 30 are provided along the first direction. In the boundary region 200 in the present example, the gate trench portion 40 is not provided.

The gate trench portion 40 in the present example may have two linear portions 39 which extend along the second direction (trench portions which are straight shaped along the second direction) and the edge portion 41 which connects the two linear portions 39. The second direction in FIG. 2 is the Y axis direction.

At least a part of the edge portion 41 is preferably provided in a curved shape in a top view. By connecting between end portions of the two linear portions 39 in the Y axis direction by the edge portion 41, it is possible to reduce the electric field strength at the end portions of the linear portions 39.

In the transistor section 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a straight shape extending in the second direction, or may have linear portions 29 and an edge portion 31 similar to the gate trench portion 40. The semiconductor device 100 illustrated in FIG. 2 includes both of the dummy trench portion 30 with a straight shape having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom portion in a depth direction of each trench portion is covered with the well region 11 at the end portion in the Y axis direction of each trench portion. With this configuration, the electric field strength on the bottom portion of each trench portion can be reduced.

The mesa portion 60 is provided between each trench portion in the first direction. The mesa portion 60 refers to a region sandwiched between the trench portions inside the semiconductor substrate 10. As an example, an upper end of the mesa portion 60 is the upper surface of the semiconductor substrate 10. A depth position of a lower end of the mesa portion 60 is the same as a depth position of a lower end of the trench portion. The mesa portion 60 in the present example is provided extending in the second direction (Y axis direction) along the trench on the upper surface of the semiconductor substrate 10. The mesa portion 60 of the transistor section 70, the mesa portion 60 of the diode section 80, and the mesa portion 60 of the boundary region 200 may have different structures. When the mesa portion 60 is simply mentioned in the present specification, this may refer to each of the mesa portion 60 of the transistor section 70, the mesa portion 60 of the diode section 80, and the mesa portion 60 of the boundary region 200.

The base regions 14 are provided in the mesa portions 60 of the transistor section 70 and the boundary region 200. The base region 14 is a region of the second conductivity type. The base region 14 in the present example is of the P type. A doping concentration of the base region 14 of the boundary region 200 may be the same as, or may be different from, a doping concentration of the base region 14 of the transistor section 70. In the base region 14 exposed on the upper surface of the semiconductor substrate 10 in the mesa portions 60 of the transistor section 70 and the boundary region 200, a region arranged closest to the active-side gate runner 131 is set as a base region 14-e. While FIG. 2 illustrates the base region 14-e arranged in one end portion of each mesa portion 60 in the second direction, the base region 14-e is also arranged in another end portion of each mesa portion 60.

In the mesa portion 60 of the transistor section 70, the emitter region 12 of a first conductivity type and the contact region 15 of the second conductivity type are provided in a region sandwiched by the base regions 14-e in the top view. In the mesa portion 60 of the boundary region 200, the contact region 15 of the second conductivity type may be provided in a region sandwiched by the base regions 14-e in the top view. The contact region 15 is a region of the second conductivity type having a higher doping concentration than that of the base region 14. The emitter region 12 in the present example is of the N+ type, and the contact region 15 is of the P+ type. The emitter region 12 and the contact region 15 may be provided between the base region 14 and the upper surface of the semiconductor substrate 10 in the depth direction.

In the mesa portion 60 of the diode section 80, an anode region 17 is provided. The anode region 17 is a region of the second conductivity type. The anode region 17 in the present example is of the P type. In the anode region 17 exposed on the upper surface of the semiconductor substrate 10 in the mesa portion 60 of the diode section 80, a region arranged closest to the active-side gate runner 131 is set as an anode region 17-e. While FIG. 2 illustrates the anode region 17-e arranged in one end portion in the second direction of the mesa portion 60 of the diode section 80, the anode region 17-e is also arranged in another end portion.

In the mesa portion 60 of the diode section 80, the contact region 15 of the second conductivity type may be provided in a region sandwiched by the anode regions 17-e in the top view. The contact region 15 is a region of the second conductivity type having a higher doping concentration than that of the base region 14. The contact region 15 may be provided between the anode region 17 and the upper surface of the semiconductor substrate 10 in the depth direction. Note that a configuration may be adopted where in the mesa portion 60 of the diode section 80, the anode region 17 is provided to an entire surface in the region sandwiched between the anode regions 17-e in the top view, and the contact region 15 is not provided.

The mesa portion 60 of the transistor section 70 includes the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact region 15 and the emitter region 12 of the mesa portion 60 are alternately arranged along the second direction of the trench portion (the Y axis direction).

In another example, the contact region 15 and the emitter region 12 of the mesa portion 60 may be provided in a stripe pattern along the second direction of the trench portion (the Y axis direction). For example, the emitter region 12 is provided in a region in contact with the trench portion, and the contact region 15 is provided in a region sandwiched between the emitter regions 12.

The mesa portions 60 of the diode section 80 and the boundary region 200 are not provided with the emitter region 12. The boundary region 200 may be a region where a channel is not formed in the mesa portion 60. The boundary region 200 may be a region where the channel is formed at a proportion lower than that of the transistor section 70.

The anode region 17 may be provided in a region sandwiched by the contact regions 15 in an upper surface of the mesa portion 60 of the diode section 80. The anode region 17 may be arranged in an entire region sandwiched between the contact regions 15. The mesa portion 60 of the boundary region 200 may have a structure that is the same as or may have a structure different from that of the mesa portion 60 of the diode section 80. In the mesa portion 60 of the boundary region 200 in the present example, the contact region 15 is provided in the entire region that is sandwiched between the base regions 14-e. In other words, an area of the contact region 15 of the mesa portion 60 of the boundary region 200 may be greater than an area of the contact region 15 of the mesa portion 60 of the diode section 80. In this case, holes in the semiconductor substrate 10 can be easily extracted to the emitter electrode 52 via the mesa portion 60 of the boundary region 200.

In addition, in the mesa portion 60 of the boundary region 200, an impurity region of the N type may be provided which has a doping concentration approximately the same as that of the emitter region 12 or lower than that of the emitter region 12. Note that in that case, the boundary region 200 is not provided with the gate trench portion 40. In the following explanation, the impurity region may be referred to as an accumulation region.

A trench portion in a boundary position between the transistor section 70 and the boundary region 200 is the dummy trench portion 30. In the mesa portion 60 of the boundary region 200, the impurity region of the N type is not in contact with the gate trench portion 40, and therefore a current that is greater than that of the transistor section 70 does not flow into the boundary region 200. In this way, the injection of the holes from the mesa portion 60 of the boundary region 200 can be suppressed, and a reverse recovery loss can be reduced.

The contact hole 54 is provided above each mesa portion 60. The contact hole 54 is arranged in the region sandwiched between the base regions 14-e. The contact hole 54 in the present example is provided above each region of the contact region 15, the base region 14, and the emitter region 12. The contact hole 54 is not provided in regions corresponding to the base region 14-e and the well region 11. The contact hole 54 may be arranged at a center of the mesa portion 60 in the first direction (X axis direction).

In the diode section 80, a cathode region 82 of the N+ type is provided in a region in direct contact with the lower surface of the semiconductor substrate 10. On the lower surface of the semiconductor substrate 10, a collector region 22 of the P+ type may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line. In addition, in the transistor section 70 and the boundary region 200, the collector region 22 of the P+ type is provided in the region in direct contact with the lower surface of the semiconductor substrate 10.

The cathode region 82 is arranged away from the well region 11 in the Y axis direction. With this configuration, the distance between a region of the P type (the well region 11) having a comparatively high doping concentration and formed up to the deep position, and the cathode region 82 is ensured, so that the breakdown voltage can be improved. The end portion in the Y axis direction of the cathode region 82 in the present example is arranged farther away from the well region 11 than the end portion in the Y axis direction of the contact hole 54. In another example, the end portion in the Y axis direction of the cathode region 82 may be arranged between the well region 11 and the contact hole 54.

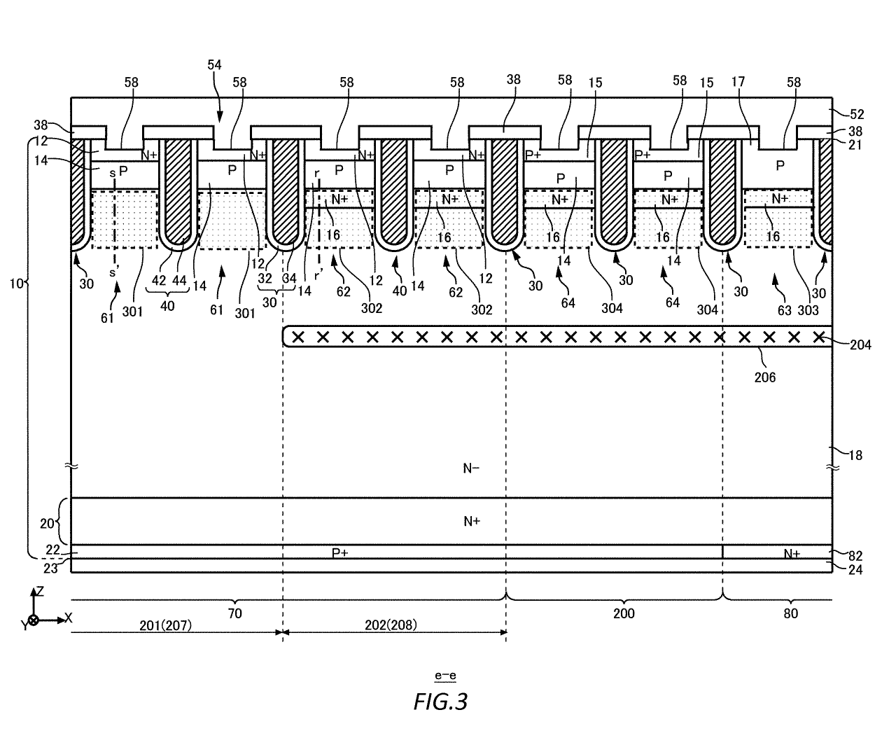

FIG. 3 illustrates an example of a cross section e-e in FIG. 2. The cross section e-e is the XZ plane passing through an emitter region 12 and a cathode region 82. The semiconductor device 100 in the present example includes the semiconductor substrate 10, the interlayer insulating film 38, the emitter electrode 52, and a collector electrode 24 in the cross section.

The interlayer insulating film 38 is provided on the upper surface of the semiconductor substrate 10. The interlayer insulating film 38 is a film including at least one layer of an insulating film such as silicate glass to which an impurity such as boron or phosphorous is added, a thermal oxide film, and other insulating films. The interlayer insulating film 38 is provided with a contact hole 54 described with reference to FIG. 2.

The emitter electrode 52 is provided above the interlayer insulating film 38. The emitter electrode 52 is in contact with a front surface 21 of the semiconductor substrate 10 through the contact hole 54 of the interlayer insulating film 38. The collector electrode 24 is provided on the lower surface 23 of the semiconductor substrate 10. The emitter electrode 52 and the collector electrode 24 are formed of a metal material such as aluminum. In the present specification, the direction (Z axis direction) in which the emitter electrode 52 is connected to the collector electrode 24 is referred to as a depth direction. As described below in detail, the emitter electrode 52 may have a barrier metal containing titanium in a part in contact with the front surface 21 of the semiconductor substrate 10. The barrier metal may have a titanium nitride layer or may have a stacked structure of a titanium nitride layer and a titanium layer. As described below in detail, the emitter electrode 52 may have a plug portion made of tungsten or the like with which the inside of the contact hole 54 is filled.

The semiconductor substrate 10 has a drift region 18 of the N type or the N- type, for example, of the first conductivity type. The drift region 18 in the present example is a region of the N- type. The drift region 18 is provided in each of the transistor section 70, the diode section 80, and the boundary region 200. The base region 14 and the contact region 15 are provided above the drift region 18.

The semiconductor substrate 10 also has an accumulation region 16 of the N type or the N+ type, for example, of the first conductivity type. The accumulation region 16 and the emitter region 12 described above are regions of the first conductivity type which have doping concentrations higher than that of the drift region 18. Both the accumulation region 16 and the emitter region 12 in the present example are regions of the N+ type.

The accumulation region 16 accumulates holes below the accumulation region 16. Providing the accumulation region 16 having a high concentration between the drift region 18 and the base region 14 can increase a carrier injection enhancement effect (IE effect) and reduce an on-voltage. The doping concentration of the accumulation region 16 may be ten times or more, may be 50 times or more, or may be 100 times or more, greater than the doping concentration of the drift region 18.

The transistor section 70 has a first transistor region 201 including the emitter region 12 and the gate trench portion 40, and a second transistor region 202 including the emitter region 12 and the gate trench portion 40. The second transistor region 202 is provided between the first transistor region 201 and the diode section 80.

As described above, the transistor section 70 has the boundary region 200 provided to be closer to the diode section 80 than the second transistor region 202. The accumulation region 16 is provided from the mesa portion 60 of the second transistor region 202 to the mesa portion 60 of the boundary region 200. In the present example, the accumulation region 16 is provided from the mesa portion 60 of the second transistor region 202 to the mesa portion 60 of the boundary region 200 and the mesa portion 60 of the diode section 80. Note that a configuration may be adopted where the accumulation region 16 is not provided in the mesa portion 60 of the diode section 80.

In the present example, the front surface of the semiconductor substrate 10 in the boundary region 200 where the accumulation region 16 is provided in the mesa portion 60 is the contact region 15. When the front surface of the semiconductor substrate 10 in the boundary region 200 is set as the contact region 15, hole injection increases, but hole injection can be suppressed in the accumulation region 16 of the mesa portion 60 of the boundary region 200.

In the present example, a plurality of the mesa portions 60 include one or more first mesa portions 61, one or more second mesa portions 62, one or more third mesa portions 63, and one or more fourth mesa portions 64. The first mesa portion 61 and the second mesa portion 62 are provided in the transistor section 70. More specifically, the first mesa portion 61 is provided in the first transistor region 201, and the second mesa portion 62 is provided in the second transistor region 202. That is, the second mesa portion 62 is arranged between the first mesa portion 61 and the diode section 80. A third mesa portion 63 is provided in the diode section 80, and a fourth mesa portion 64 is provided in the boundary region 200.

In the first mesa portion 61 of the first transistor region 201 and the second mesa portion 62 of the second transistor region 202, the emitter region 12 of the N+ type and the base region 14 of the P type are provided in the stated order from the front surface 21 side of the semiconductor substrate 10.

The emitter region 12 is exposed on the front surface 21 of the semiconductor substrate 10 and is provided in contact with the gate trench portion 40. The emitter region 12 may be in contact with the trench portions on both sides of the mesa portion 60.

In the transistor section 70, the base region 14 is provided below the emitter region 12. The base region 14 in the transistor section 70 in the present example is provided in contact with the emitter region 12. In the transistor section 70, the base region 14 may be in contact with the trench portions on both sides of the first mesa portion 61 and the second mesa portion 62.

The first mesa portion 61 of the first transistor region 201 has a first region 301 of the first conductivity type which is provided between a depth position of a lower end of the base region 14 and a depth position of a lower end of the trench portion. In the present example, the first region 301 of the first conductivity type is the drift region 18 of the first conductivity type.

The second mesa portion 62 of the second transistor region 202 has a second region 302 of the first conductivity type which is provided between a depth position of a lower end of the base region 14 and a depth position of a lower end of the trench portion. The second region 302 includes the accumulation region 16 of the first conductivity type. A doping concentration of the second region 302 of the second mesa portion 62 is higher than that of the first region 301 of the first mesa portion 61. With this configuration, hole injection near the diode section 80 can be suppressed. In addition, a width of the boundary region 200 in the X axis direction can be narrowed.

The diode section 80 has the anode region 17 of the second conductivity type provided above the drift region 18. The anode region 17 in the diode section 80 is in contact with the front surface 21 of the semiconductor substrate 10. A doping concentration of the anode region 17 of the second conductivity type may be the same as, or may be different from, a doping concentration of the base region 14 of the second conductivity type. The third mesa portion 63 of the diode section 80 has a third region 303 of the first conductivity type which is provided between a depth position of a lower end of the anode region 17 and a depth position of a lower end of the trench portion. The third region 303 in the present example includes the accumulation region 16. A doping concentration of the third region 303 of the first conductivity type of the third mesa portion 63 is higher than that of the drift region 18 of the first conductivity type.

A doping concentration of the anode region 17 of the second conductivity type in the diode section 80 may be greater than, may be less than, or may be the same as, the doping concentration of the base region 14 in the transistor section 70. In addition, the doping concentration of the anode region 17 may be greater than, may be less than, or may be the same as, the doping concentration of the base region 14 in the boundary region 200. As an example, the doping concentration of the anode region 17 of the second conductivity type in the diode section 80 is greater than or equal to the doping concentrations of the base regions 14 in the transistor section 70 and the boundary region 200.

In the fourth mesa portion 64 of the boundary region 200 in the present example, the contact region 15 of the P+ type is provided in contact with the front surface 21 of the semiconductor substrate 10. In the fourth mesa portion 64, the base region 14 is also provided between the contact region 15 and the drift region 18. The fourth mesa portion 64 has a fourth region 304 of the first conductivity type which is provided between the depth position of the lower end of the base region 14 and the depth position of the lower end of the trench portion. The fourth region 304 includes the accumulation region 16. A doping concentration of the fourth region 304 of the first conductivity type of the fourth mesa portion 64 is higher than that of the first region 301 of the first conductivity type of the first mesa portion 61.

The first region 301 to the fourth region 304 may be each provided across an entirety of the respective mesa portions 60 in the X axis direction. The first region 301 to the fourth region 304 may be each provided so as to cover the entire lower surface of the base region 14 of the respective mesa portions 60. Doping concentrations of the plurality of first regions 301 and the like in each of the transistor section 70, the diode section 80, and the boundary region 200 may be the same or different in each of the mesa portions 60. As an example, the doping concentration of the second region 302 of the second transistor region 202 may be higher in the second mesa portion 62 that is closer to the diode section 80.

As described above, the first region 301 to the fourth region 304 are each the region provided between the depth position of the lower end of the base region 14 and the depth position of the lower end of the trench portion. The depth position of the lower end of the base region 14 in the present example is uniform in the transistor section 70, the diode section 80, and the boundary region 200. In addition, the depth position of the lower end of the trench portion in the present example is uniform in the transistor section 70, the diode section 80, and the boundary region 200. Therefore, in the present example, the widths of the first region 301, the second region 302, the third region 303, and the fourth region 304 in the depth direction are substantially uniform. When an interval of mutually adjacent trench portions is uniform in the transistor section 70, the diode section 80, and the boundary region 200, volumes of the first region 301, the second region 302, the third region 303, and the fourth region 304 may be substantially uniform.

The first mesa portion 61, the second mesa portion 62, the third mesa portion 63, and the fourth mesa portion 64 are provided with trench contact portions 58. The trench contact portion 58 is a part in which a metal electrode such as the emitter electrode 52 is provided inside the semiconductor substrate 10. The trench contact portion 58 can be formed by forming a groove on the front surface 21 of the semiconductor substrate 10 exposed by the contact hole 54 and filling an inside of the groove with the metal electrode. A region where the first mesa portion 61 or the like is in contact with the metal electrode such as the emitter electrode 52 is equivalent to a contact portion.

Widths of the trench contact portions 58 in the depth direction in the present example are uniform in all of the first mesa portion 61, the second mesa portion 62, the third mesa portion 63, and the fourth mesa portion 64, but may be different from each other. For example, the trench contact portion 58 and the contact region 15 of the second mesa portion 62 may be deeper towards the drift region 18 side than the trench contact portion 58 and the contact region 15 of the first mesa portion 61.

In each of the transistor section 70, the diode section 80, and the boundary region 200, the N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 in the present example may have two or more concentration peaks in the depth direction (Z axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region 22 of a P+ type and the cathode region 82 of the N+ type.

In the transistor section 70, the collector region 22 of the P+ type is provided below the buffer region 20. An acceptor concentration of the collector region 22 is higher than an acceptor concentration of the base region 14. The collector region 22 may include an acceptor which is the same as or may include different from an acceptor of the base region 14. The acceptor of the collector region 22 is, for example, boron.

Below the buffer region 20 in the diode section 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above.

In the boundary region 200, the collector region 22 of the P+ type is provided below the buffer region 20. The collector region 22 of the boundary region 200 may have the same doping concentration as the collector region 22 of the transistor section 70. The boundary position between the cathode region 82 and the collector region 22 in the X axis direction may be set as a boundary position between the diode section 80 and the boundary region 200 in the X axis direction.

In another example, in the boundary region 200, a part or all of the collector regions 22 may be replaced with the cathode region 82. When the cathode region 82 is provided for a lower surface of the boundary region 200, a region where the contact regions 15 and the anode regions 17 are alternately arranged in the region sandwiched between the anode regions 17-e may be set as the diode section 80, and a region where the contact region 15 is arranged in the entire region sandwiched between the base regions 14-e may be set as the boundary region 200. When the cathode region 82 is provided on the lower surface of the boundary region 200, the boundary region 200 may be considered as a part of the diode section 80.

Among the trench portions adjacent to the mesa portion in which the channel is formed, the trench portion arranged closest to the diode section 80 in the X axis direction may be set as a boundary position between the transistor section 70 and the boundary region 200 or the diode section 80 in the X axis direction. Of the two trench portions in contact with the emitter region 12 arranged closest to the diode section 80 in the X axis direction, the trench portion on the diode section 80 side may be the dummy trench portion 30. The dummy trench portion 30 in this case may be set as the boundary position between the transistor section 70 and the boundary region 200 or the diode section 80 in the X axis direction.

The boundary region 200 may be provided with the emitter region 12. Note that in that case, the boundary region 200 is not provided with the gate trench portion 40. Moreover, the trench portion in the boundary position between the transistor section 70 and the boundary region 200 is the dummy trench portion 30. That is, transistor operations do not occur in the boundary region 200. The boundary region 200 may be provided with the gate trench portion 40. Note that in that case, the boundary region 200 is not provided with the emitter region 12, or even when the boundary region 200 is provided with the emitter region 12, the emitter region 12 is not in contact with the gate trench portion 40. That is, transistor operations do not occur in the boundary region 200.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the front surface 21 side of the semiconductor substrate 10. Each trench portion is provided penetrating the base region 14 from the front surface 21 of the semiconductor substrate 10 up to a position below the base region 14 (until reaching the drift region 18). In a region where at least any of the emitter region 12 or a contact region 15 is provided, each trench portion also penetrates these doping regions. A configuration in which a trench portion penetrates a doping region is not limited to a configuration which is manufactured by forming a doping region and forming a trench portion in this order. The configuration of the trench portions penetrating the doping region also includes a configuration of forming the trench portions and then forming the doping region between the trench portions.

As described above, the transistor section 70 is provided with the gate trench portion 40 and the dummy trench portion 30. The diode section 80 and the boundary region 200 in the present example are provided with the dummy trench portion 30 and are not provided with the gate trench portion 40. Note that the gate trench portion 40 may be arranged or the dummy trench portion 30 may be arranged at the boundary between the boundary region 200 and the transistor section 70.

Note that the boundary region 200 is a buffering structure for arranging different structures of the transistor section 70 and the diode section 80 side by side. Therefore, the width of the boundary region 200 in the X axis direction may be short. For example, in the boundary region 200, one or more fourth mesa portions 64 may be provided, and the boundary region 200 may not be provided.

The boundary region 200 may include a plurality of fourth mesa portions 64 in the X axis direction. This allows the effects of the transistor section 70 on the characteristics of the diode section 80, for example, the effects of the operation of the gate trench portion 40 and the discharge or injection of holes in the contact region 15, on the forward voltage and reverse recovery characteristics, to be suppressed. The number of mesa portions refers to the number of mesa portions arranged side by side in the X axis direction.

The gate trench portion 40 has a gate trench, a gate insulating film 42, and a gate conductive portion 44 that are provided on the front surface 21 of the semiconductor substrate 10. The gate insulating film 42 is provided covering the inner wall of the gate trench. The gate insulating film 42 may be formed by oxidizing or nitriding a semiconductor in the inner wall of the gate trench. Inside the gate trench, the gate conductive portion 44 is provided on an inner side relative to the gate insulating film 42. In other words, the gate insulating film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered with the interlayer insulating film 38 on the front surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 has a dummy trench, a dummy insulating film 32, and a dummy conductive portion 34 that are provided on the front surface 21 of the semiconductor substrate 10. The dummy conductive portion 34 is electrically connected to the emitter electrode 52. The dummy insulating film 32 is provided covering an inner wall of the dummy trench. The dummy conductive portion 34 is provided inside the dummy trench and is provided on an inner side relative to the dummy insulating film 32. The dummy insulating film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in the present example are covered with the interlayer insulating film 38 at the front surface 21 of the semiconductor substrate 10. Note that bottom portions of the dummy trench portion 30 and the gate trench portion 40 may be formed in a curved-surface shape (curved-line shape in the cross section) that is convex downward.

The semiconductor device 100 in the present example includes a lifetime control region 206 provided on the front surface side relative to the center of the semiconductor substrate 10 in the depth direction of the semiconductor substrate 10. The lifetime control region 206 includes a lifetime killer which adjusts a lifetime of carriers. The lifetime control region 206 decreases a threshold voltage and also decreases a switching loss of the semiconductor device 100.

The lifetime control region 206 in the present example is a region where a lifetime of charge carriers is locally short. The charge carriers are electrons or holes. The charge carriers may be simply referred to as carriers. The lifetime control region 206 in the present example is formed through injection of charged particles such as helium ions from the front surface 21 side of the semiconductor substrate 10. In the present example, a concentration distribution of helium or the like of the semiconductor substrate 10 in the depth direction may have such a shape that draws a hem from the lifetime control region 206 to the front surface 21 of the semiconductor substrate 10. In other words, the concentration (/cm³) of helium or the like may monotonically decrease from the lifetime control region 206 to the front surface 21.

The concentration of helium or the like in the front surface 21 may be greater than 0. On the other hand, also in a direction towards the lower surface 23 from the lifetime control region 206, the concentration of helium or the like may have such a shape that draws a hem. Note that the concentration of helium or the like more steeply decreases in the hem towards the lower surface 23 than that in the hem towards the front surface 21. The concentration of helium or the like in the lower surface 23 is lower than the concentration of helium or the like in the front surface 21. The concentration of helium or the like in the front surface 21 may be less than or equal to a measurement limit or may be 0. Note that the lifetime control region 206 may be formed through injection of charged particles such as helium ions from the lower surface 23 side of the semiconductor substrate 10.

By injecting charged particles such as helium ions into the semiconductor substrate 10, lattice defects 204 such as vacancies are formed in a vicinity of the injection position. The lattice defects 204 generate recombination centers. The lattice defects 204 may be mainly composed of vacancies such as monovacancies (V) or divacancies (VV), may be dislocations, may be interstitial atoms, or may be transition metals or the like. For example, atoms adjacent to the vacancies have dangling bonds. In a broad sense, the lattice defects 204 may also include donors and acceptors, but in the present specification, the lattice defects 204 mainly composed of vacancies may be referred to as vacancy-type lattice defects, vacancy-type defects, or simply lattice defects. In the present specification, the lattice defects 204 may be simply referred to as recombination centers or lifetime killers as recombination centers contributing to recombination of carriers.

The lifetime killer may be formed through injection of helium ions to the semiconductor substrate 10. A helium chemical concentration may be set as a density of the lattice defect 204. Note that since the lifetime killer formed by injecting helium ions may be terminated by hydrogen existing in the buffer region 20, the depth position of the density peak of the lifetime killer may not be identical to the depth position of the helium chemical concentration peak. In addition, when injecting hydrogen ions into the semiconductor substrate 10, the lifetime killer may be formed in a passed-through region of hydrogen ions that is more on the injection surface side than the projected range.

The lattice defect 204 is an example of the lifetime killer. In FIG. 3, the lattice defects 204 at the injection positions of the charged particles are schematically indicated by X marks. In a region where many lattice defects 204 remain, the carriers are captured by the lattice defects 204, and thus the lifetime of the carriers is shortened. By adjusting the lifetime of carriers, characteristics of the diode section 80 such as a reverse recovery time and a reverse recovery loss can be adjusted. In the depth direction of the semiconductor substrate 10, a position where the carrier lifetime illustrates a local minimum may be set as a depth position of the lifetime control region 206.

The lifetime control region 206 is arranged on the front surface 21 side of the semiconductor substrate 10. The front surface 21 side is a region from the center position of the semiconductor substrate 10 in the depth direction to the front surface 21 of the semiconductor substrate 10. The lifetime control region 206 in the present example is arranged below the lower end of the trench portion.

In a case where the lifetime control region 206 is formed through irradiation of highly penetrating particle beams such as electron beams, lattice defects are formed in a substantially uniform manner from the front surface 21 to the lower surface 23 of the semiconductor substrate 10. Even at this time, the depth position of the lifetime control region 206 may be regarded as being arranged on the front surface 21 side of the semiconductor substrate 10.

The lifetime control region 206 extends from the diode section 80 to the second transistor region 202. When the semiconductor device 100 has the boundary region 200, the lifetime control region 206 is also provided in the boundary region 200. The lifetime control region 206 may be provided in the entire diode section 80 in the X axis direction. The lifetime control region 206 is also provided in the entire boundary region 200. The lifetime control region 206 in the present example is provided below the accumulation region 16.

The lifetime control region 206 of the diode section 80 and the lifetime control region 206 of the transistor section 70 are provided in the same depth positions. In the transistor section 70, the second transistor region 202 may be an adjustment region 208 in which the lifetime control region 206 is provided, and the first transistor region 201 may be a non-adjustment region 207 in which the lifetime control region 206 is not provided.

Herein, a configuration may be adopted in which a boundary between the adjustment region 208 and the non-adjustment region 207 does not match a boundary between the first transistor region 201 and the second transistor region 202, and for example, the lattice defect 204 (the lifetime control region 206) may be provided from the second transistor region 202 to a part of the first transistor region 201.

The adjustment region 208 is a region overlapping the lifetime control region 206 in the top view. The non-adjustment region 207 is a region that is not overlapping the lifetime control region 206 in the top view. The non-adjustment region 207 is a region where the carrier lifetime in the same depth position as the lifetime control region 206 is longer than the carrier lifetime of the lifetime control region 206 of the diode section 80. The non-adjustment region 207 may be a region to which charged particles such as helium ions for forming the lifetime killer such as the lattice defect 204 are not injected. A chemical concentration (/cm³) of helium or the like in the non-adjustment region 207 may be the same as a chemical concentration of the charged particles at a center of the drift region 18 in the Z axis direction.

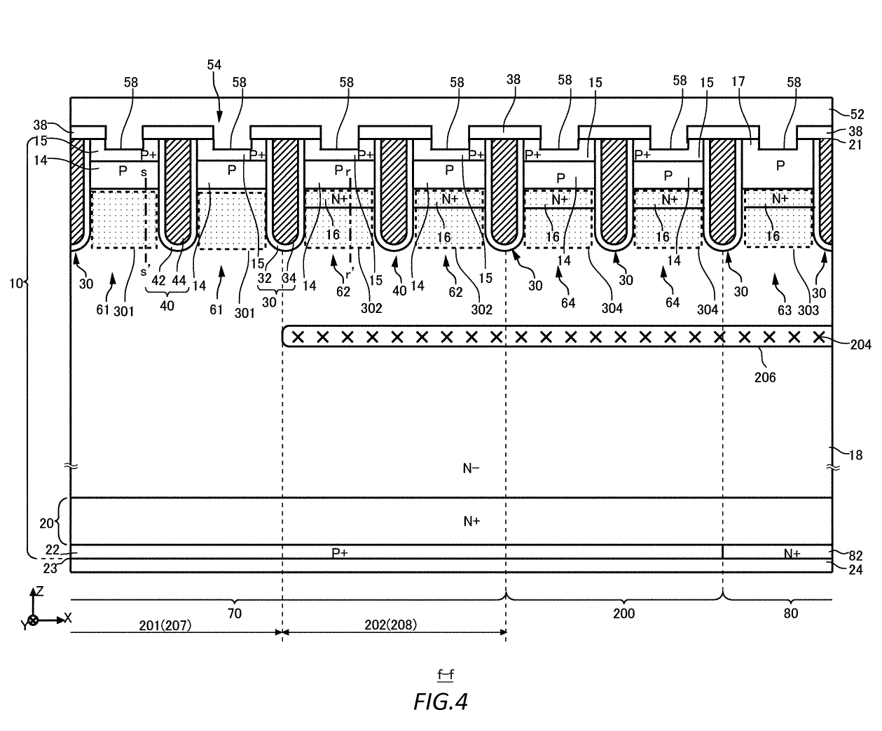

FIG. 4 is a view illustrating an example of a cross section f-f in FIG. 2. The cross section f-f is an X-Z plane passing through a contact region 15 and a cathode region 82. The cross section in the present example has a structure in which the emitter region 12 in the example illustrated in FIG. 3 is replaced with the contact region 15. A structure other than the contact region 15 is similar to that of FIG. 3.

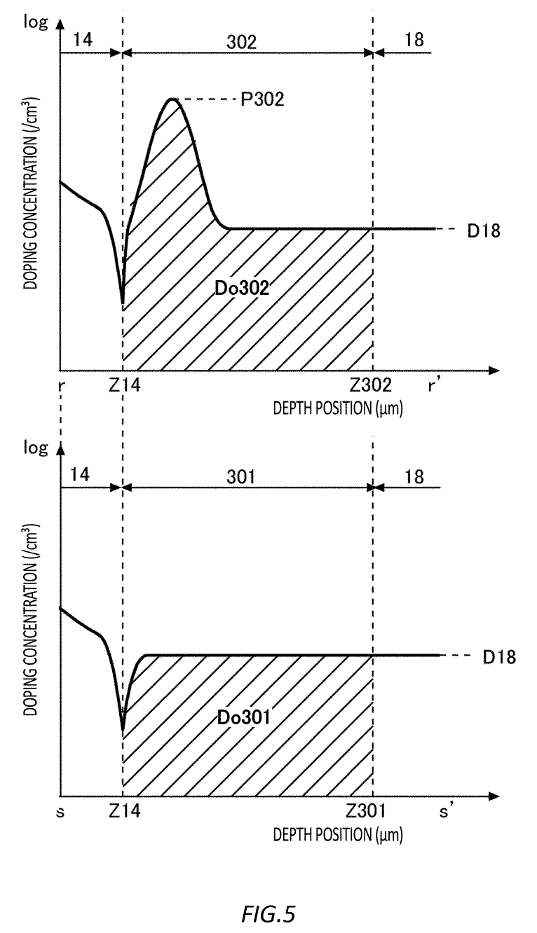

FIG. 5 illustrates an example of a doping concentration distribution along a line r-r' and a line s-s' in FIG. 3. The line r-r' is a line parallel to the Z axis which passes through the second region 302, and the line s-s' is a line parallel to the Z axis which passes through the first region 301.

An integrated concentration of a dopant of the first conductivity type in the second region 302 is greater than an integrated concentration of a dopant of the first conductivity type in the first region 301. It may be mentioned that a dose amount (/cm²) of an N type dopant in the second region 302 is greater than a dose amount of an N type dopant in the first region 301. A value obtained by integrating a doping concentration of each region may be used as a dose amount of each region.

The doping concentration of the first region 301 in the present example is greater than or equal to the doping concentration of the drift region 18 and less than the doping concentration of the second region 302. A peak value may be used as a value of the doping concentration in each region. The doping concentration of the first region 301 may be the same as the doping concentration of the drift region 18. In other words, the drift region 18 provided in the first mesa portion 61 may be treated as the first region 301. The doping concentration of the first region 301 may be higher than the doping concentration of the drift region 18. The doping concentration of the first region 301 may be half or less, may be 1/10 or less, or may be 1/100 or less of the doping concentration the second region 302.

A P-N junction is provided in a boundary between the second region 302 and the base region 14 in the present example. A depth position of the boundary is set as Z14. A doping concentration distribution in the second region 302 has a peak. A doping concentration at a local maximum of the peak is set as P302. In addition, a doping concentration of the drift region 18 is set as D18. The peak concentration P302 is higher than the doping concentration D18. A depth position of the lower end of the second region 302 is set as Z302.

A P-N junction is provided in a boundary between the first region 301 and the base region 14 in the present example. A depth position of the boundary is set as Z14. A doping concentration of the first region 301 in the present example is the same as the doping concentration of the drift region 18. In the present example, the number of peaks of the doping concentration in the first region 301 is 0. The doping concentration of the first region 301 in the depth direction in the present example may be constant. A depth position of the lower end of the first region 301 is set as Z301.

A dose amount (ions/cm²) per unit area of dopant ions for the first region 301 is set as Do 301. A value obtained by integrating the doping concentration of the first region 301 from the depth position Z14 to Z301 may be used as the dose amount Do 301 of the first region 301. A dose amount (ions/cm²) per unit area of dopant ions for the second region 302 is set as Do 302. A value obtained by integrating the doping concentration of the second region 302 from the depth position Z14 to Z302 may be used as the dose amount Do 302 of the second region 302. Areas of portions hatched with diagonal lines in FIG. 5 correspond to the respective dose amounts.

The dose amount Do 302 is higher than the dose amount Do 301. The dose amount Do 302 may be twice or more, may be ten times or more, or may be 100 times or more, greater than the dose amount Do 301. In addition, the doping concentration D18 of the first region 301 is lower than the peak concentration P302. Note that in the present example, it may be mentioned that the number of peaks of the doping concentration of the second region 302 is higher than the number of peaks of the doping concentration of the first region 301.

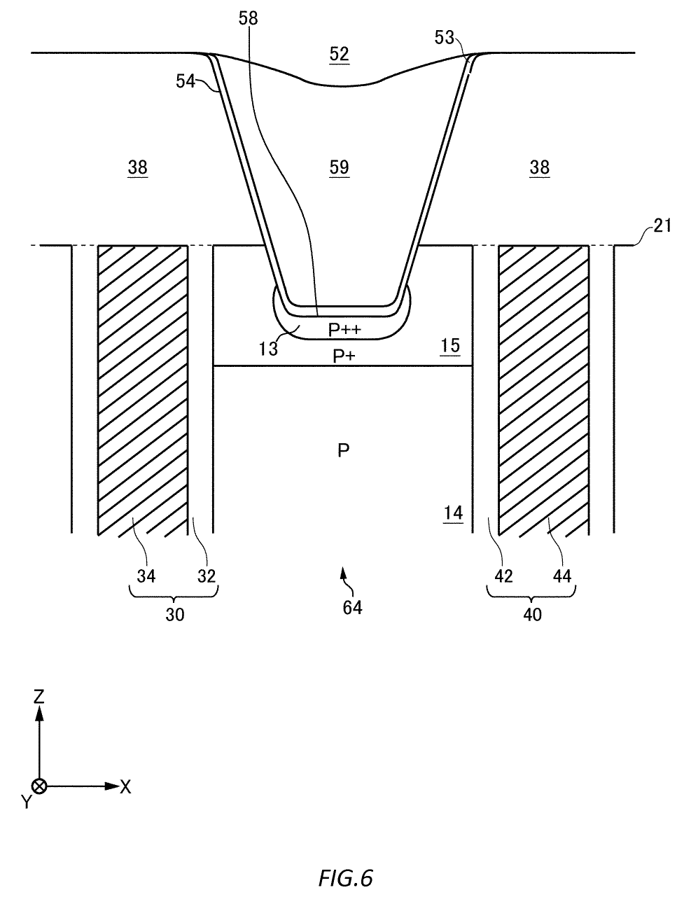

FIG. 6 is an enlarged view in a vicinity of the trench contact portion 58 in the boundary region 200. In the fourth mesa portion 64 of the boundary region 200, barrier metals 53 are provided on a side wall and a bottom surface of the contact hole 54. The barrier metal 53 may be provided on an entire bottom surface of the contact hole 54. A material of the barrier metal 53 may be titanium or a titanium compound. When the semiconductor substrate 10 is silicon, the barrier metal 53 may react with the semiconductor substrate 10 to form a silicide.

In the contact hole 54, a plug portion 59 is provided on an inner side of the barrier metal 53. A material of the plug portion 59 may be tungsten. The material of the plug portion 59 may be the same material as the emitter electrode 52. The barrier metal 53 and the plug portion 59 are also similarly provided in each of the contact holes 54 of the transistor section 70 and the diode section 80.

In at least a part of the mesa portion 60, the plug region 13 may be provided in a region in contact with the lower end of the contact portion. The plug region 13 is a region which is provided above the drift region 18 and has a doping concentration higher than that of the base region 14. The plug region 13 in the present example is provided below the trench contact portion 58. The plug region 13 in the present example is in contact with a bottom surface of the trench contact portion 58. The plug region 13 may be in contact with a side wall of the trench contact portion 58. The plug region 13 is a region of the second conductivity type which has a doping concentration higher than that of the base region 14. The plug region 13 in the present example has a doping concentration higher than that of the contact region 15. The plug region 13 in the present example is a region of the P++ type.

The plug region 13 may be provided extending in the trench extension direction on the bottom surface of the trench contact portion 58. The plug region 13 may be provided on an entire bottom surface of the trench contact portion 58. By providing each plug region 13, the holes can be easily extracted in each mesa portion 60. Thus, it is possible to suppress reduction in withstand capability.

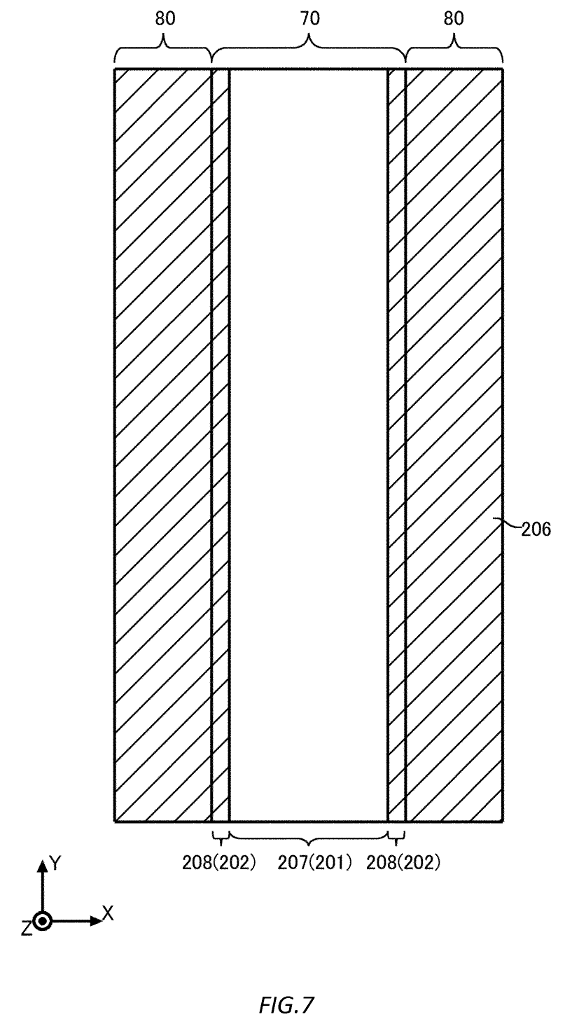

FIG. 7 illustrates an arrangement example of an adjustment region 208 and a non-adjustment region 207 in the top view. The arrangement in the present example may be applied to the semiconductor device 100 in any of the modes described in the present specification. In FIG. 7, two pieces of diode section 80 and one piece of the transistor section 70 are illustrated, and other regions are omitted. In addition, in FIG. 7, a region in which the lifetime control region 206 is provided is hatched with diagonal lines.

In the present example, in the transistor section 70, the adjustment region 208 in which the lifetime control region 206 is provided may include the second transistor region 202, and the non-adjustment region 207 in which the lifetime control region 206 is not provided may match the first transistor region 201. The adjustment region 208 may also be provided in the entire diode section 80 in the X axis direction. In addition, the adjustment region 208 is provided in a region in contact with the diode section 80 or the boundary region 200 in the transistor section 70. An area of the first transistor region 201 in the transistor section 70 may be larger than an area of the second transistor region 202. That is, in the present example, an area of the non-adjustment region 207 in the transistor section 70 may be larger than an area of the adjustment region 208 in the transistor section 70.

In the transistor section 70, the number of the first mesa portions 61 may be higher than the number of the second mesa portions 62. With this configuration, even when turn-off of the second transistor region 202 is slower than that of the first transistor region 201, it is possible to suppress local current concentration. In the transistor section 70, the threshold voltage of the second mesa portion 61 may be lower than the threshold voltage of the first mesa portion 62. By adjusting the depth of the trench contact portion 58 in the second mesa portion 62 and the dose amount of each plug region 13, the threshold voltage of each mesa portion 60 can be adjusted. Note that the threshold voltage of the mesa portion 60 is a voltage at which at least one channel region transitions from being off to being on in the mesa portion 60 in question.

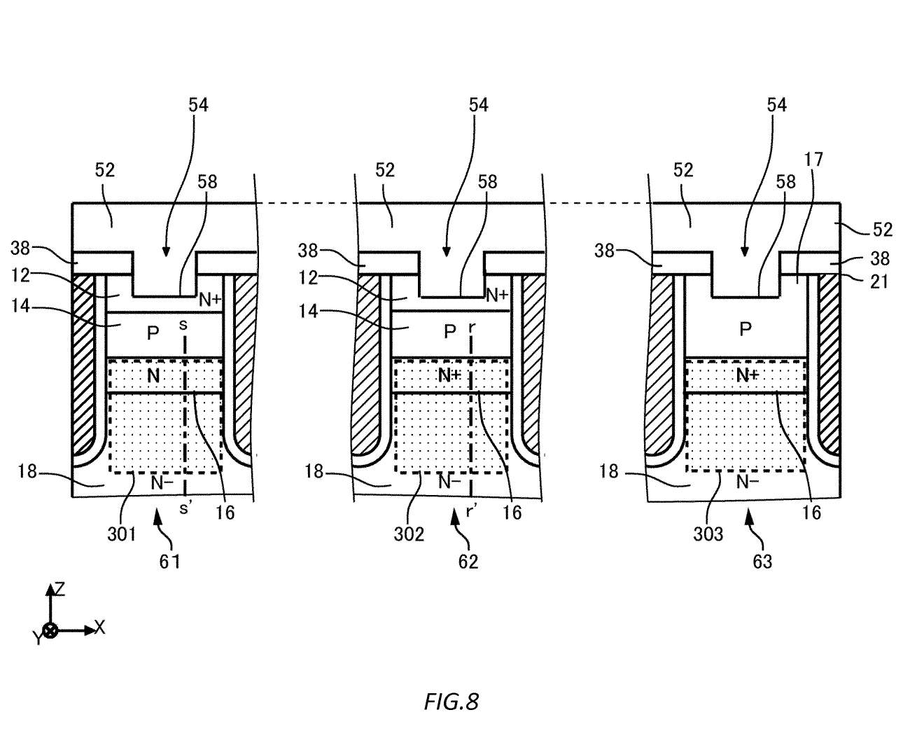

FIG. 8 illustrates another configuration example of the first mesa portion 61, the second mesa portion 62, and the third mesa portion 63. The first region 301 in the first mesa portion 61 in the present example includes the accumulation region 16 of the N type. Each of the second region 302 in the second mesa portion 62 and the third region 303 in the third mesa portion 63 in the present example includes the accumulation region 16 of the N+ type. A structure other than the first region 301, the second region 302, and the third region 303 may be similar to the embodiment described by using FIG. 1 to FIG. 7, and redundant descriptions are omitted. In addition, as an example, the third region 303 may have a doping concentration similar to that of the second region 302, and redundant descriptions are omitted. The same also applies to a plurality of following embodiments.

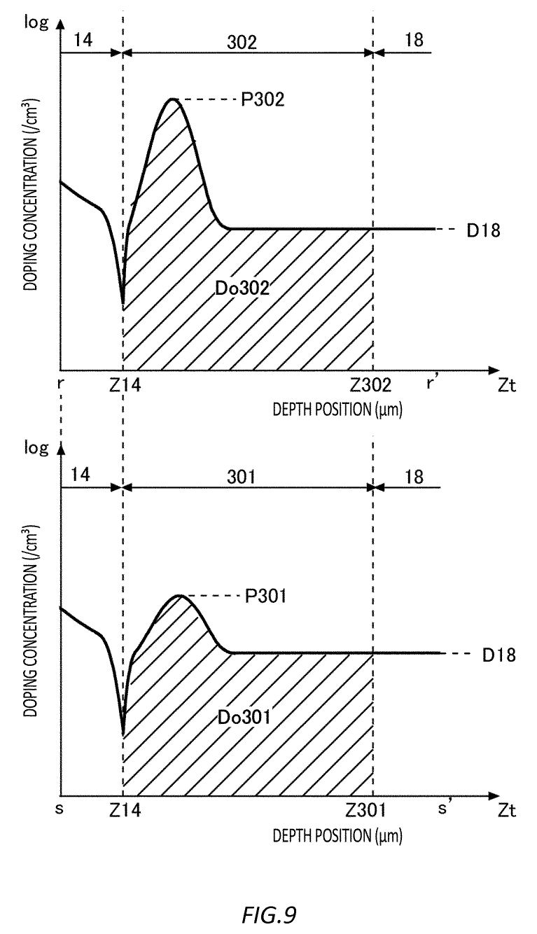

FIG. 9 illustrates an example of a doping concentration distribution along the line r-r' and the line s-s' in FIG. 8. As being different from the example of FIG. 5, a doping concentration distribution in the first region 301 in the present example has a peak. A doping concentration at a local maximum of the peak is set as P301. The peak concentration P301 is higher than the doping concentration D18.

An integrated concentration of a dopant of the first conductivity type in the second region 302 is greater than an integrated concentration of a dopant of the first conductivity type in the first region 301. It may be mentioned that the dose amount Do 302 is greater than the dose amount Do 301. The dose amount Do 302 may be twice or more, may be ten times or more, or may be 100 times or more, greater than the dose amount Do 301.

A peak of the doping concentration of the second region 302 is greater than a peak of the doping concentration of the first region 301. In the present example, the peak concentration P302 is greater than the peak concentration P301. The peak concentration P301 may be twice or more, may be ten times or more, or may be 100 times or more, greater than the peak concentration P302.

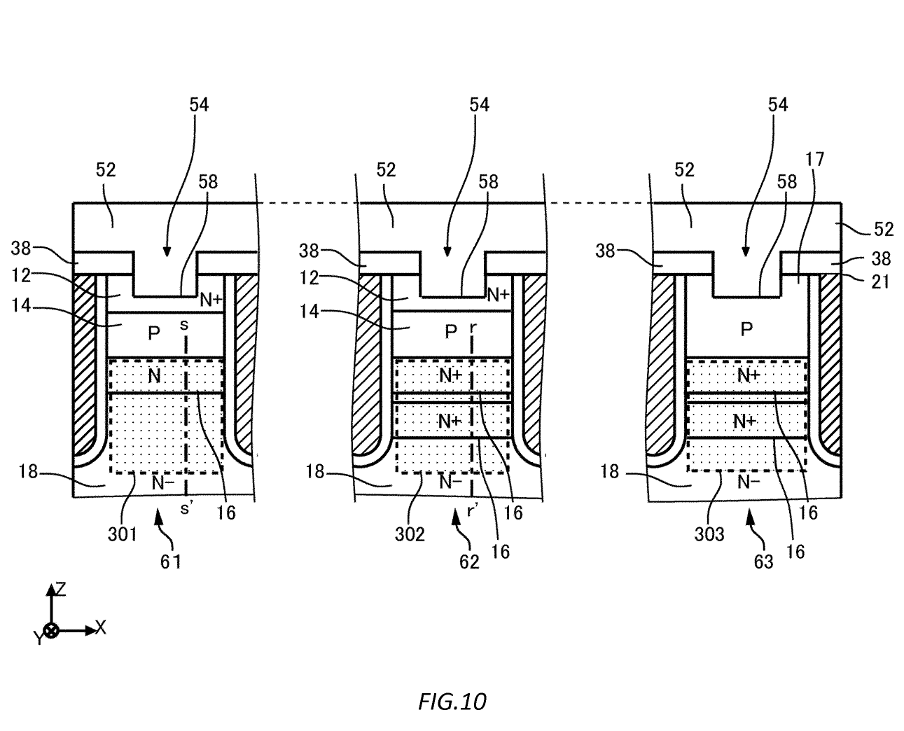

FIG. 10 illustrates another configuration example of the first mesa portion 61, the second mesa portion 62, and the third mesa portion 63. In the present example, as a different aspect from the configuration example of FIG. 8, the second mesa portion 62 and the third mesa portion 63 have a plurality of accumulation regions 16 in the depth direction. The plurality of accumulation regions 16 in the second mesa portion 62 and the like may have regions with doping concentrations lower than the doping concentration of the accumulation regions 16 interposed between one another, and for example, may have regions of the N- type interposed similarly as in the drift regions 18. In another example, the region between the plurality of accumulation regions 16 may have a doping concentration higher than that of the drift region 18. Each of the first region 301 of the first mesa portion 61, the second region 302 of the second mesa portion 62, and the third region 303 of the third mesa portion 63 has one or more peaks of the doping concentration in the depth direction.

The second region 302 in the second mesa portion 62 in the present example has a greater number of accumulation regions 16 than the number of accumulation regions 16 included in the first region 301 in the first mesa portion 61. In FIG. 10, the first region 301 has one accumulation region 16, and the second region 302 has two accumulation regions 16. In other words, the number of peaks of the doping concentration of the second region 302 in the present example is two.

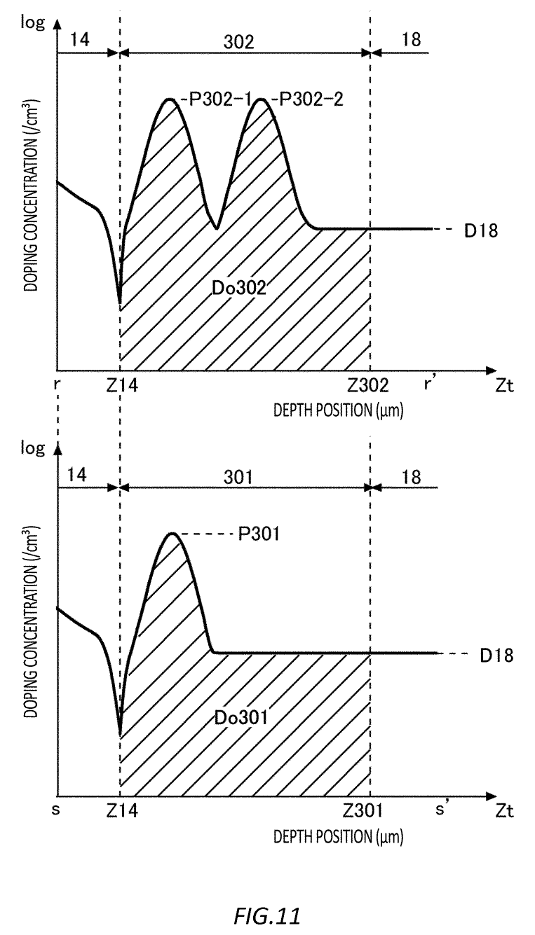

FIG. 11 illustrates an example of a doping concentration distribution along the line r-r' and the line s-s' in FIG. 10. One doping concentration P302-1 and another doping concentration P302-2 in the second region 302 may be the same or may be different from each other.

An integrated concentration of a dopant of the first conductivity type in the second region 302 is greater than an integrated concentration of a dopant of the first conductivity type in the first region 301. It may be mentioned that the dose amount Do 302 is greater than the dose amount Do 301. The dose amount Do 302 may be twice or more, may be ten times or more, or may be 100 times or more, greater than the dose amount Do 301.

The peak of the doping concentration of the second region 302 may be equal to the peak of the doping concentration of the first region 301, or may be greater than the peak of the doping concentration of the first region 301. In the present example, the peak concentration P302 is equal to the peak concentration P301. The peak concentration P302 may be one time or more, may be twice or more, may be ten times or more, or may be 100 times or more, greater than the peak concentration P301. The number of peaks P302-1 and P302-2 of the doping concentration of the second region 302 is greater than the number of the peaks P301 of the doping concentration of the first region 301.

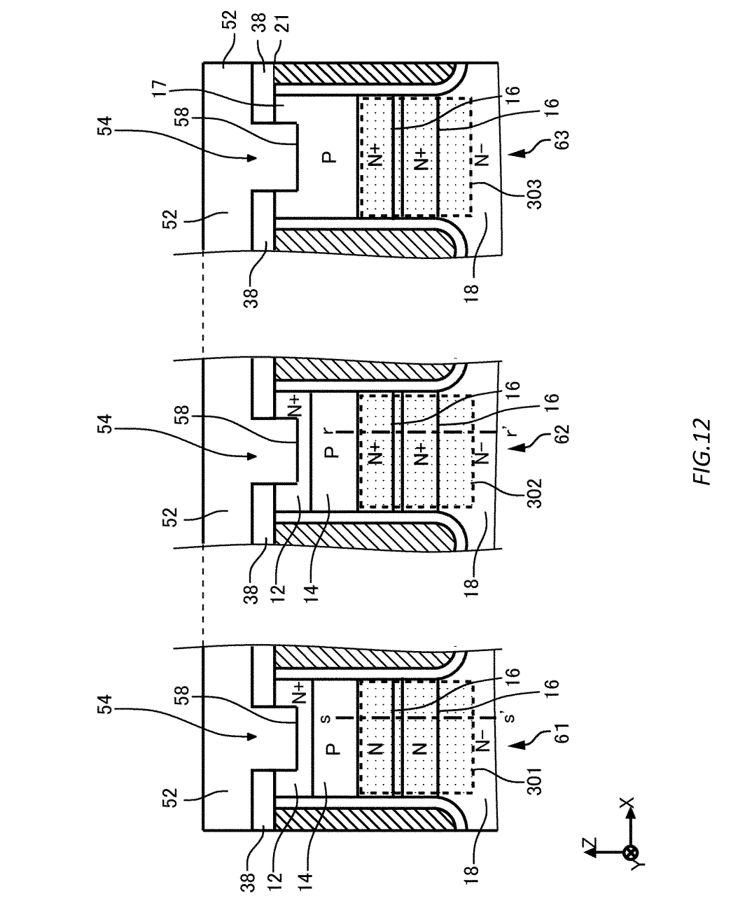

FIG. 12 illustrates another configuration example of the first mesa portion 61, the second mesa portion 62, and the third mesa portion 63. In the present example, as a different aspect from the configuration example of FIG. 10, the first mesa portion 61 also has the plurality of the accumulation regions 16 in a depth direction. The plurality of accumulation regions 16 in the first mesa portion 61 may have regions with doping concentrations lower than the doping concentration of the accumulation regions 16 interposed between one another, and for example, may have regions of the N- type interposed similarly as in the drift regions 18.

In another example, the region between the plurality of accumulation regions 16 may have a doping concentration higher than that of the drift region 18. Each of the first region 301 of the first mesa portion 61, the second region 302 of the second mesa portion 62, and the third region 303 of the third mesa portion 63 has a plurality of peaks of the doping concentration in the depth direction.

The second region 302 in the second mesa portion 62 in the present example has the same number of accumulation regions 16 as the number of accumulation regions 16 included in the first region 301 in the first mesa portion 61. In FIG. 12, the first region 301 and the second region 302 have two accumulation regions 16. In other words, the numbers of peaks of the doping concentrations of the first region 301 and the second region 302 in the present example are both two. The first region 301 in the present example has two accumulation regions 16 of the N type, and the second region 302 has two accumulation regions 16 of the N+ type.

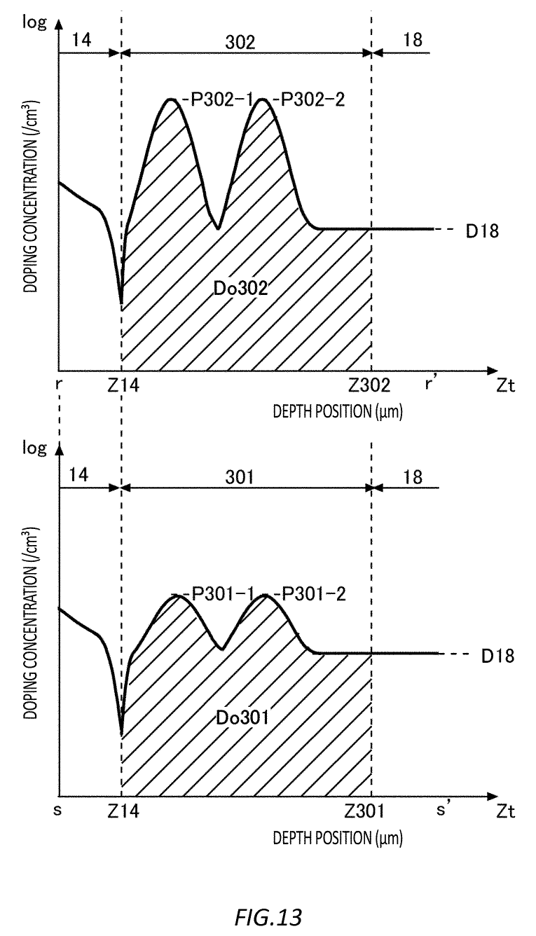

FIG. 13 illustrates an example of a doping concentration distribution along the line r-r' and the line s-s' in FIG. 12. One doping concentration P301-1 and another doping concentration P301-2 in the first region 301 may be the same or may be different from each other. Similarly, one doping concentration P302-1 and another doping concentration P302-2 in the second region 302 may be the same or may be different from each other.

An integrated concentration of a dopant of the first conductivity type in the second region 302 is greater than an integrated concentration of a dopant of the first conductivity type in the first region 301. It may be mentioned that the dose amount Do 302 is greater than the dose amount Do 301. The dose amount Do 302 may be twice or more, may be ten times or more, or may be 100 times or more, greater than the dose amount Do 301.

A peak of the doping concentration of the second region 302 is greater than a peak of the doping concentration of the first region 301. In the present example, both the peak concentrations P302-1 and P302-2 are respectively greater than the peak concentrations P301-1 and P301-2. Both the peak concentrations P302-1 and P302-2 may be twice or more, may be ten times or more, or may be 100 times or more, greater than the peak concentrations P301-1 and P301-2, respectively.

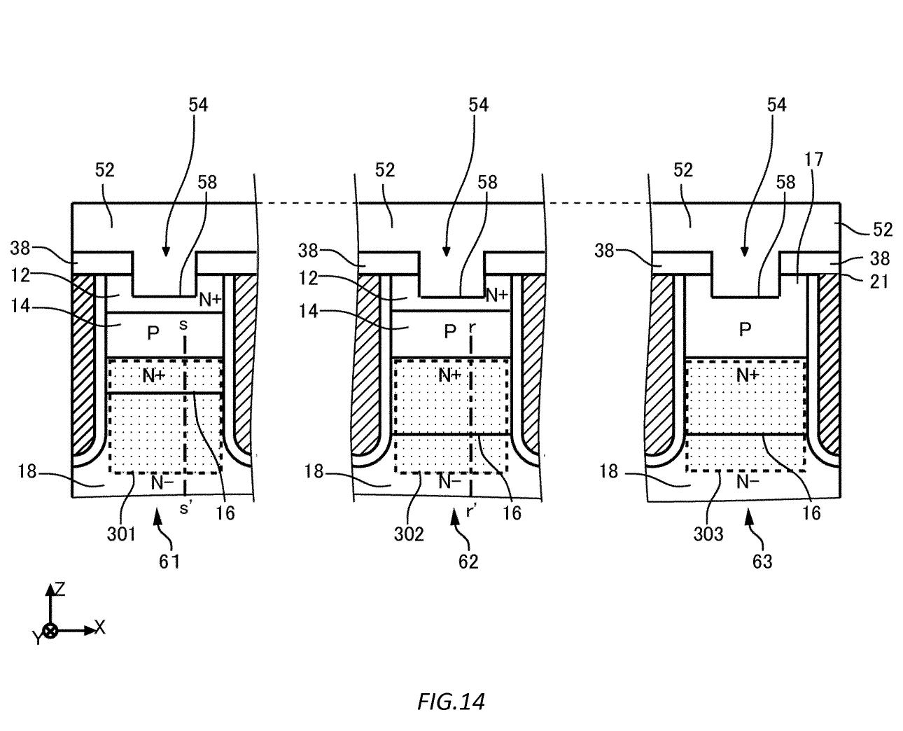

FIG. 14 illustrates another configuration example of the first mesa portion 61, the second mesa portion 62, and the third mesa portion 63. In the present example, as a different aspect from the configuration example of FIG. 10, the second region 302 in the second mesa portion 62 and the third region 303 in the third mesa portion 63 have the accumulation regions 16 with widths relatively larger in the depth direction compared to that of the first region 301 in the first mesa portion 61.

The second region 302 and the first region 301 in the present example include the accumulation regions 16 having the same doping concentration. A width of the accumulation region 16 in the depth direction in the second region 302 is greater than a width of the accumulation region 16 in the depth direction in the first region 301.

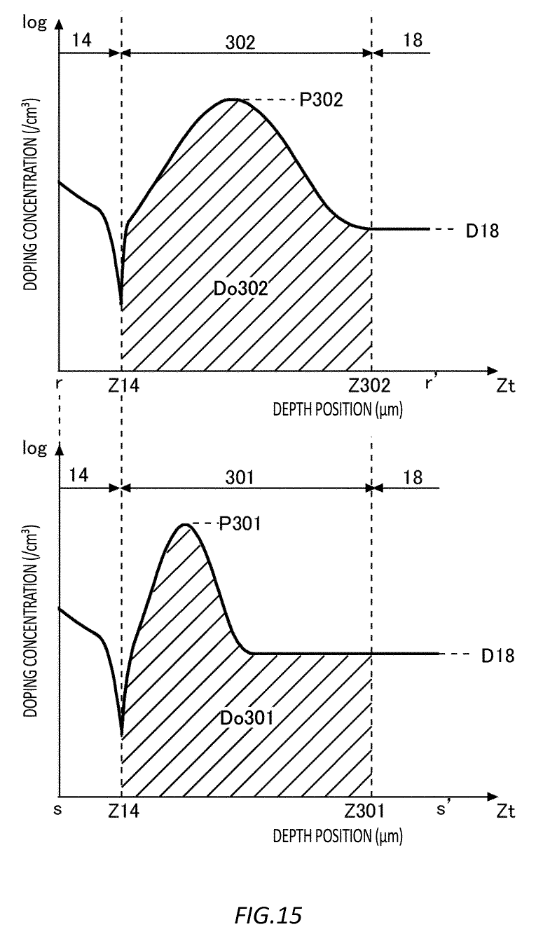

FIG. 15 illustrates an example of a doping concentration distribution along the line r-r' and the line s-s' in FIG. 14.

An integrated concentration of a dopant of the first conductivity type in the second region 302 is greater than an integrated concentration of a dopant of the first conductivity type in the first region 301. It may be mentioned that the dose amount Do 302 is greater than the dose amount Do 301. The dose amount Do 302 may be twice or more, may be ten times or more, or may be 100 times or more, greater than the dose amount Do 301.

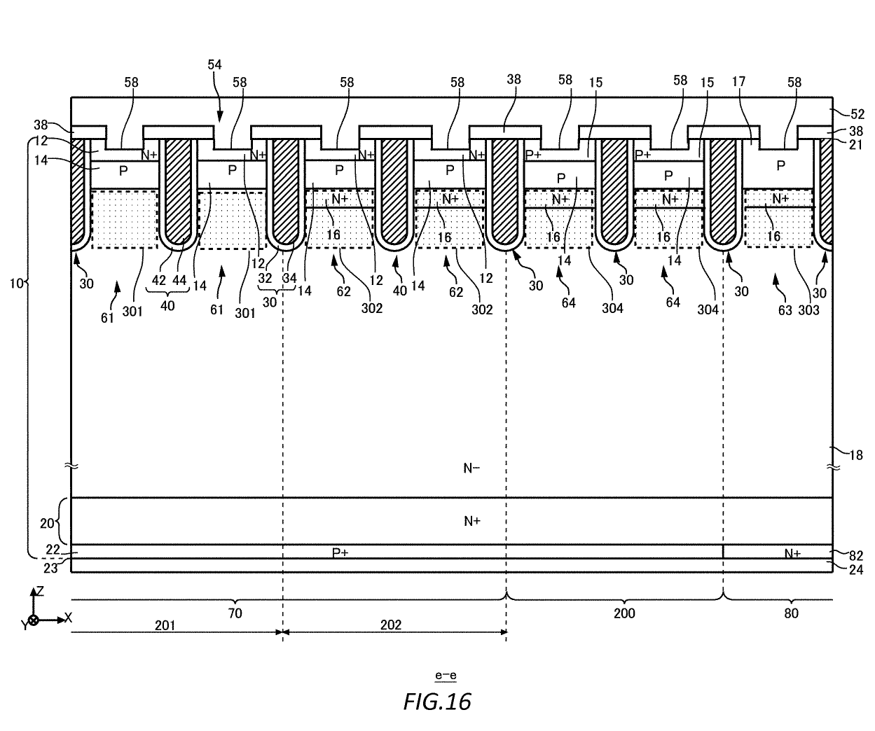

FIG. 16 illustrates another example of the cross section e-e in FIG. 2. The semiconductor device 100 in the present example is different from the semiconductor device 100 in the plurality of embodiments described by using FIG. 1 to FIG. 15 in that the semiconductor substrate 10 does not have the lifetime control region 206. The other structure in the semiconductor device 100 in the present example is similar to the structure corresponding to the semiconductor device 100 in the plurality of embodiments described by using FIG. 1 to FIG. 15, so that corresponding reference numerals are used, and redundant descriptions are omitted.

In FIG. 16, an example is illustrated in which the lifetime control region 206 is excluded from the structures illustrated in FIG. 3, but also in the structures illustrated in the other drawings, the lifetime control region 206 may be excluded.

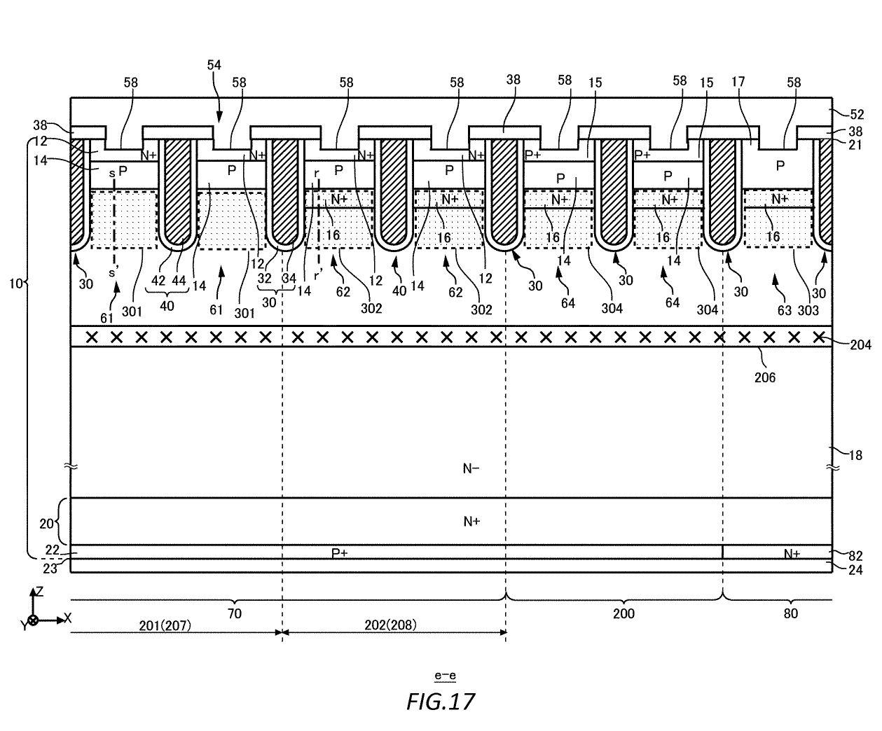

FIG. 17 illustrates another example of the cross section e-e in FIG. 2. The semiconductor device 100 in the present example is different from the semiconductor device 100 in the plurality of embodiments described by using FIG. 1 to FIG. 16 in that the semiconductor substrate 10 has the lifetime control region 206 for the entire surface and the lifetime control region 206 is continuously provided in the same depth in the transistor section 70 and the diode section 80. The other structure in the semiconductor device 100 in the present example is similar to the structure corresponding to the semiconductor device 100 in the plurality of embodiments described by using FIG. 1 to FIG. 16, so that corresponding reference numerals are used, and redundant descriptions are omitted.

In FIG. 17, an example is illustrated in which from the structure illustrated in FIG. 3, the semiconductor substrate 10 has the lifetime control region 206 for the entire surface and the lifetime control region 206 is continuously provided in the same depth in the transistor section 70 and the diode section 80, but also in the structures illustrated in the other drawings, the semiconductor substrate 10 may have the lifetime control region 206 for the entire surface and the lifetime control region 206 may be continuously provided in the same depth in the transistor section 70 and the diode section 80.

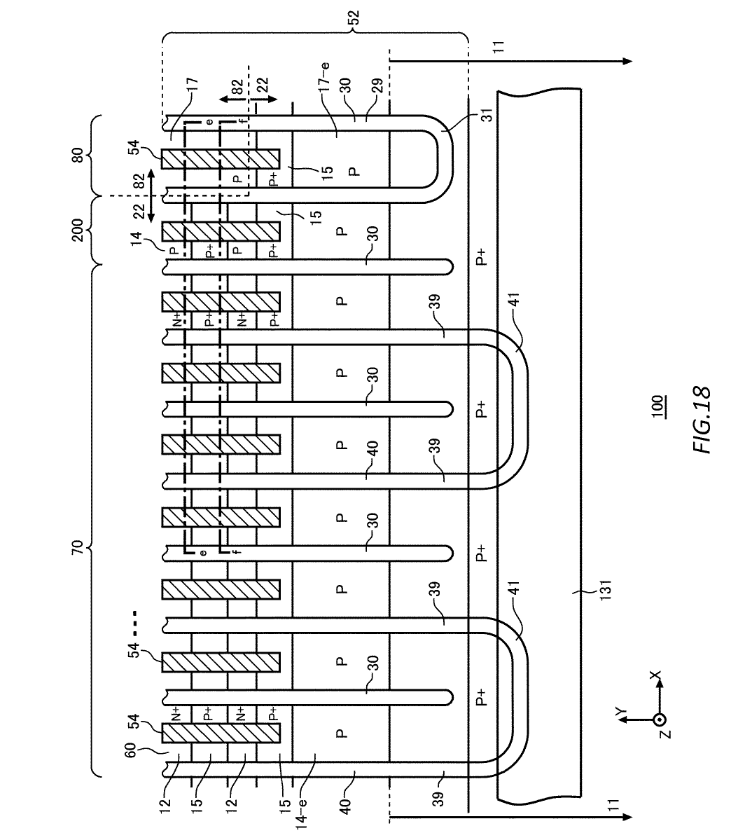

FIG. 18 illustrates another example of the enlarged view of the region D in FIG. 1. The semiconductor device 100 in the present example is different from the semiconductor device 100 in the plurality of embodiments described by using FIG. 1 to FIG. 17 in that the boundary region 200 is one mesa portion 60. The other structure in the semiconductor device 100 in the present example is similar to the structure corresponding to the semiconductor device 100 in the plurality of embodiments described by using FIG. 1 to FIG. 17, so that corresponding reference numerals are used, and redundant descriptions are omitted.

In FIG. 18, an example is illustrated in which from the structure illustrated in FIG. 2, the boundary region 200 is one mesa portion 60, but also in the structures illustrated in the other drawings, the boundary region 200 may have one mesa portion 60. In addition, in the present example, the contact region 15 and the base region 14 are alternately arranged in the Y axis direction in the mesa portion 60 of the boundary region 200. As in the present example, instead of providing the contact region 15 for the entire surface in the region sandwiched by the base regions 14-e in the top view of the mesa portion 60 of the boundary region 200, the contact region 15 may be partially provided. Note that also in a case other than the present example where the boundary region 200 has two or more mesa portions 60, the mesa portion 60 partially provided with the contact region 15 may be provided. On the other hand, also in the present example, the contact region 15 may be provide for the entire surface in the region sandwiched by the base regions 14-e in the top view of the mesa portion 60 of the boundary region 200.

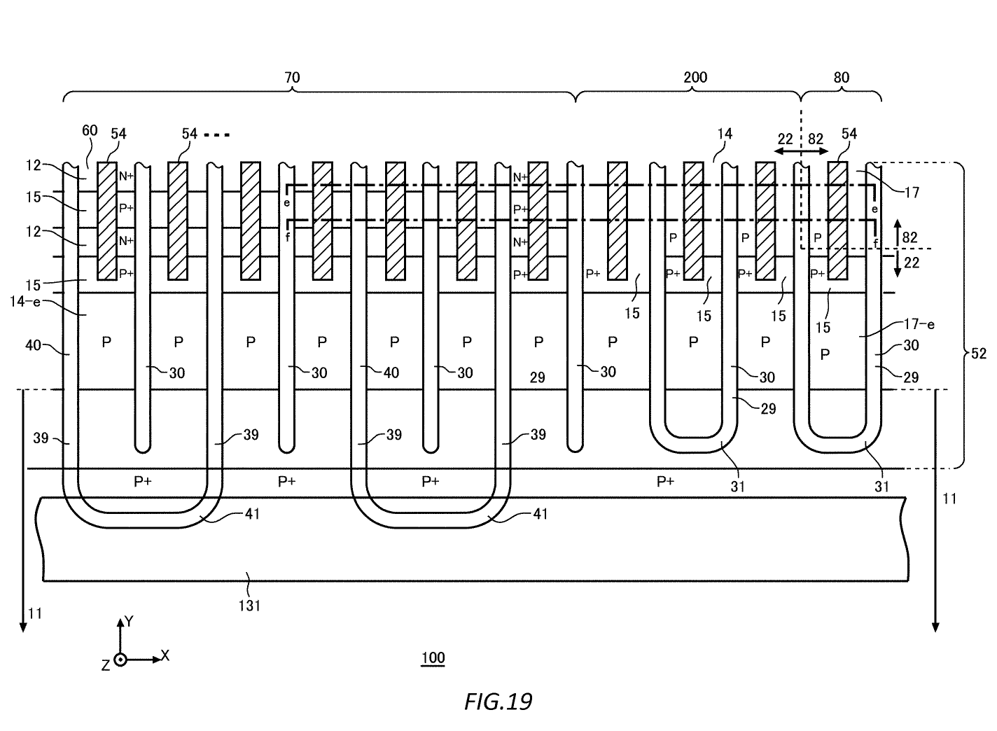

FIG. 19 illustrates another example of the enlarged view of the region D in FIG. 1. The semiconductor device 100 in the present example is provided with the plurality of mesa portions 60 in the boundary region 200. The semiconductor device 100 in the present example is different from the semiconductor device 100 in the plurality of embodiments described by using FIG. 1 to FIG. 18 in that a part of the mesa portion 60 that is adjacent to the transistor section 70 and that is in contact with the front surface 21 of the semiconductor substrate 10 in the boundary region 200 is provided with the contact region 15 and the other part of the mesa portion 60 has the base region 14 without being provided with the contact region 15. Herein, a configuration of having the base region 14 without being provided with the contact region 15 may include a case where only the region in the end portion adjacent to the base region 14-e in the region sandwiched by the base regions 14-e in the top view of the mesa portion 60 of the boundary region 200 is provided with the contact region 15 or may include a case where the entire surface has the base region 14 without being provided with the contact region 15.

The other structure in the semiconductor device 100 in the present example is similar to the structure corresponding to the semiconductor device 100 in the plurality of embodiments described by using FIG. 1 to FIG. 18, so that corresponding reference numerals are used, and redundant descriptions are omitted.

In FIG. 19, an example is illustrated in which from the structure illustrated in FIG. 2, the mesa portion 60 that is adjacent to the transistor section 70 and that is in contact with the front surface 21 of the semiconductor substrate 10 in the boundary region 200 is provided with the contact region 15 and the other part of the mesa portion 60 has the base region 14 without being provided with the contact region 15, but also in the structures illustrated in the other drawings, a configuration may be adopted in which in the upper surface of the boundary region 200, a part of the mesa portion 60 adjacent to the transistor section 70 is provided with the contact region 15 and the other part of the mesa portion 60 has the base region 14 without being provided with the contact region 15. In addition, the boundary region 200 may be composed of only the mesa portion 60 that has the base region 14 in the region sandwiched by the base region 14-e in the top view of the mesa portion 60 of the boundary region 200 and that is not provided with the contact region 15.

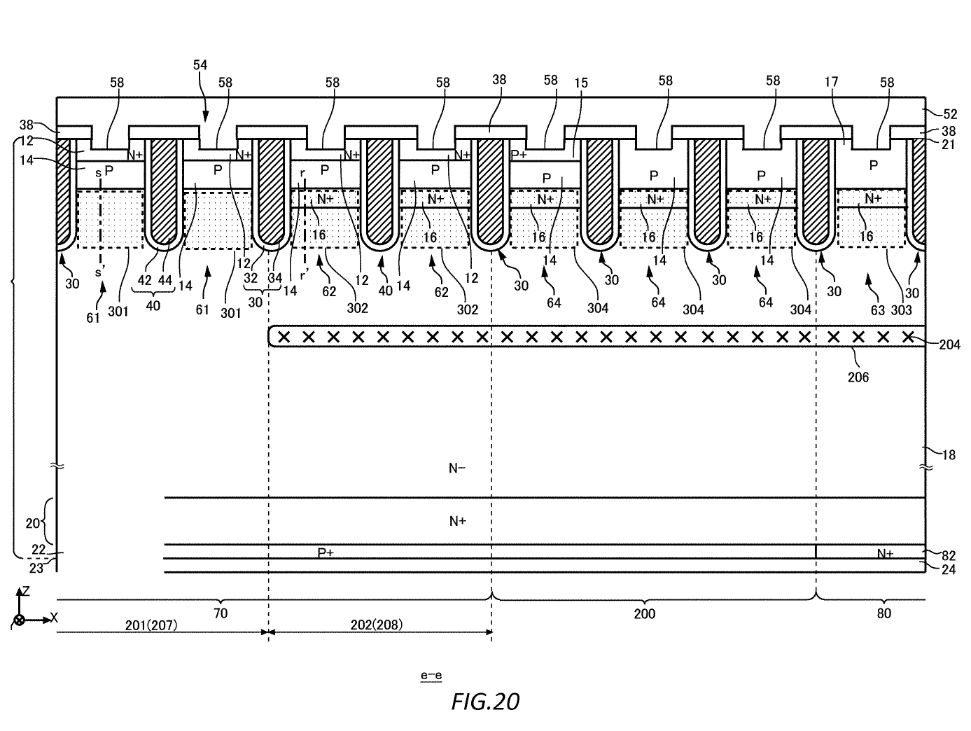

FIG. 20 illustrates an example of a cross section e-e in FIG. 19. In the boundary region 200 in the present example, the plurality of fourth mesa portions 64 are provided in the X axis direction, the fourth mesa portion 64 adjacent to the second transistor region 202 is provided with the contact region 15 in contact with the front surface 21 of the semiconductor substrate 10, and the base region 14 is provided between the contact region 15 and the drift region 18. In addition, the fourth mesa portion 64 that is not adjacent to the second transistor region 202 of the boundary region 200 in the present example is provided with the base region 14 in contact with the front surface 21 of the semiconductor substrate 10, and the base region 14 is in contact with the drift region 18.

Similarly as in the structure illustrated in FIG. 3, the plurality of fourth mesa portions 64 in the present example have the fourth regions 304 of the first conductivity type provided between the depth position of the lower end of the base region 14 and the depth position of the lower end of the trench portion. The fourth region 304 includes the accumulation region 16. A doping concentration of the fourth region 304 of the first conductivity type of the fourth mesa portion 64 is higher than that of the first region 301 of the first conductivity type of the first mesa portion 61.

The provision of the plurality of fourth mesa portions 64 in the X axis direction in the boundary region 200 in the present example can suppress the effects of the transistor section 70 on the characteristics of the diode section 80, for example, the effects of the operation of the gate trench portion 40 and the discharge or injection of holes in the contact region 15 on the forward voltage and reverse recovery characteristics.

While the present invention has been described by way of the embodiments above, the technical scope of the present invention is not limited to the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

Note that the operations, procedures, steps, stages, or the like of each process performed by a device, system, program, and method illustrated in the claims, embodiments, or diagrams can be performed in any order as long as the order is not indicated by "prior to," "before," or the like and as long as the output from a previous process is not used in a later process. Even if the process flow is described using phrases such as "first" or "next" in the claims, embodiments, or diagrams, it does not necessarily mean that the process must be performed in this order.

### EXPLANATION OF REFERENCES

10: semiconductor substrate;

12: emitter region;

13: plug region;

14: base region;

15: contact region;

16: accumulation region;

17: anode region;

18: drift region;

20: buffer region;

21: front surface;

22: collector region;

23: lower surface;

24: collector electrode;

29: linear portion;

30: dummy trench portion;

31: edge portion;

32: dummy insulating film;

34: dummy conductive portion;

38: interlayer insulating film;

39: linear portion;

40: gate trench portion;

41: edge portion;

42: gate insulating film;

44: gate conductive portion;

52: emitter electrode;

53: barrier metal;

54: contact hole;

58: trench contact portion;

59: plug portion;

60: mesa portion;

61: first mesa portion;

62: second mesa portion;

63: third mesa portion;

64: fourth mesa portion;

70: transistor section;

80: diode section;

81: extension region;

82: cathode region;

90: edge termination structure portion;

100: semiconductor device;

130: outer circumferential gate runner;

131: active-side gate runner;

160: active section;

162: end side;

164: gate pad;

200: boundary region;

201: first transistor region;

202: second transistor region;

204: lattice defect;

206: lifetime control region;

207: non-adjustment region;

208: adjustment region;

301: first region;

302: second region;

303: third region.

What is claimed is:

1. A semiconductor device comprising:
a transistor section;
a diode section;
a drift region of a first conductivity type which is provided to a semiconductor substrate;
a plurality of trench portions which extend in a predetermined trench extension direction on a front surface side of the semiconductor substrate;
a base region of a second conductivity type which is provided above the drift region;
an emitter region which is provided to a front surface of the semiconductor substrate and which is of the first conductivity type with a doping concentration higher than that of the drift region; and
a contact region which is provided above the drift region and which is of the second conductivity type with a doping concentration higher than that of the base region, wherein
the plurality of trench portions have gate trench portions,
the transistor section has
a first transistor region including the emitter region and the gate trench portion, and
a second transistor region which includes the emitter region and the gate trench portion and which is provided between the first transistor region and the diode section, wherein
a first mesa portion of the first transistor region has a first region of the first conductivity type which is provided between a depth position of a lower end of the base region and a depth position of a lower end of the trench portion, and
a second mesa portion of the second transistor region has a second region which is provided between a depth position of a lower end of the base region and a depth position of a lower end of the trench portion and which is of the first conductivity type with a doping concentration higher than that of the first region.

2. The semiconductor device according to claim 1, comprising:
an accumulation region which is provided above the drift region and which is of the first conductivity type with a doping concentration higher than that of the drift region, wherein
the accumulation region is provided from the second mesa portion of the second transistor region to a third mesa portion of the diode section.

3. The semiconductor device according to claim 1, wherein
the transistor section has a boundary region provided to be closer to the diode section than the second transistor region.

4. The semiconductor device according to claim 3, comprising:
an accumulation region which is provided above the drift region and which is of the first conductivity type with a doping concentration higher than that of the drift region, wherein
the accumulation region is provided from the second mesa portion of the second transistor region to a fourth mesa portion of the boundary region.

5. The semiconductor device according to claim 4, wherein
a front surface of the semiconductor substrate in the boundary region is the contact region.

6. The semiconductor device according to claim 1, wherein
the first region is the drift region.

7. The semiconductor device according to claim 1, wherein
a peak of a doping concentration of the second region is greater than a peak of a doping concentration of the first region.

8. The semiconductor device according to claim 1, wherein
a number of peaks of a doping concentration of the second region is greater than a number of peaks of a doping concentration of the first region.

9. The semiconductor device according to claim 1, comprising:
an accumulation region which is provided above the drift region and which is of the first conductivity type with a doping concentration higher than that of the drift region, wherein
the second region and the first region include the accumulation regions with a same doping concentration, and
a width of the accumulation region in a depth direction in the second region is greater than a width of the accumulation region in the depth direction in the first region.

10. The semiconductor device according to claim 1, wherein
an integrated concentration of a dopant of the first conductivity type in the second region is greater than an integrated concentration of a dopant of the first conductivity type in the first region.

11. The semiconductor device according to claim 1, wherein
the diode section has an anode region of the second conductivity type which is provided above the drift region,
a third mesa portion of the diode section has a third region of the first conductivity type which is provided between a depth position of a lower end of the anode region and a depth position of a lower end of the trench portion, and
the third region has the first conductivity type with a doping concentration higher than that of the drift region.

12. The semiconductor device according to claim 11, wherein
a doping concentration of the anode region is greater than or equal to a doping concentration of the base region.

13. The semiconductor device according to claim 11, wherein
a doping concentration of the anode region is identical to a doping concentration of the base region.

14. The semiconductor device according to claim 1, comprising:
a lifetime control region provided on a front surface side relative to a center of the semiconductor substrate in a depth direction of the semiconductor substrate.

15. The semiconductor device according to claim 14, wherein
the lifetime control region extends from the diode section to the second transistor region.

16. The semiconductor device according to claim 14, comprising:
an accumulation region which is provided above the drift region and which is of the first conductivity type with a doping concentration higher than that of the drift region, wherein
the lifetime control region is provided below the accumulation region.

17. The semiconductor device according to claim 14, wherein
the second transistor region is an adjustment region in which the lifetime control region is provided, and
the first transistor region is a non-adjustment region in which the lifetime control region is not provided.

18. The semiconductor device according to claim 1, wherein
the semiconductor substrate does not include a lifetime control region.

19. The semiconductor device according to claim 2, wherein
the transistor section has a boundary region provided to be closer to the diode section than the second transistor region.

20. The semiconductor device according to claim 19, comprising:
an accumulation region which is provided above the drift region and which is of the first conductivity type with a doping concentration higher than that of the drift region, wherein
the accumulation region is provided from the second mesa portion of the second transistor region to a fourth mesa portion of the boundary region.
